(19) United States
(12) Patent Application Publication
(10) Pub. No.: US 2004/0070312 A1
(43) Pub. Date: Apr. 15, 2004

(54) Integrated circuit and process for fabricating the same

(75) Inventors: David Penunuri, Fountain Hills, AZ (US); Kurt W. Eisenbeiser, Tempe, AZ (US); Jeffrey M. Finder, Chandler, AZ (US); Steven Voight, Gilbert, AZ (US); Steven M. Smith, Gilbert, AZ (US); Albert Alec Talin, Lucerne, CA (US)

Correspondence Address: OBLON, SPIVAK, MCCLELLAND, MAIER & NEUSTADT, P.C., 1940 DUKE STREET, ALEXANDRIA, VA, 22314, US

(73) Assignee: MOTOROLA, INC., Schaumburg, IL (US)

(21) Appl. No.: 10/267,817

(22) Filed: Oct. 10, 2002

(51) Int. Cl. H03H 9/25

(52) U.S. Cl. 310/313 A

(57) ABSTRACT

High quality epitaxial layers of monocrystalline piezoelectric materials and compound semiconductor materials can be grown overlying monocrystalline substrates (22) such as large silicon wafers by forming a compliant substrate for growing the monocrystalline layers. An accommodating buffer layer (24) comprises a layer of monocrystalline oxide spaced apart from a silicon wafer by an amorphous interface layer (28) of silicon oxide. An integrated circuit including at least one surface acoustic wave device can be formed in and over the high quality epitaxial layers.

### FIELD OF THE INVENTION

This invention relates generally to surface acoustic wave devices, to integrated circuits, and to methods for their fabrication, and more specifically to integrated circuits having at least one surface acoustic wave device and to the fabrication of the same that have a semiconductor structure with monocrystalline material layers comprised of semiconductor material, piezoelectric material, and/or other types of material such as metals and non-metals.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and electron lifetime of semiconductive layers improve as the crystallinity of the layer increases. Similarly, the free electron concentration of conductive layers and the electron charge displacement and electron energy recoverability of insulative or dielectric films improve as the crystallinity of these layers increases.

For many years, attempts have been made to grow various monolithic thin films on a foreign substrate such as silicon (Si). To achieve optimal characteristics of the various monolithic layers, however, a monocrystalline film of high crystalline quality is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of monocrystalline material to be of low crystalline quality.

If a large area thin film of high quality monocrystalline material were available at low cost, a variety of devices could advantageously be fabricated in or using that film at a low cost compared to the cost of fabricating such devices beginning with a bulk wafer of semiconductor material or in an epitaxial film of such material on a bulk wafer of monocrystalline material. In addition, if a thin film of high quality monocrystalline material could be realized beginning with a bulk wafer such as a silicon wafer, an integrated device structure could be achieved that took advantage of the best properties of both the silicon and the high quality monocrystalline material.

Accordingly, a need exists for a structure and device having a high quality monocrystalline film or layer over another monocrystalline material and for a process for making such a structure. In other words, there is a need for providing the formation of a monocrystalline substrate that is compliant with a high quality monocrystalline material layer so that true two-dimensional growth can be achieved for the formation of quality structures, devices and integrated circuits having grown monocrystalline film having the same crystal orientation as an underlying substrate. This monocrystalline material layer may be comprised of a semiconductor material, a compound semiconductor material, and other types of material such as metals and non-metals.

Furthermore, surface acoustic wave devices have several applications in the microelectronics industry. For example, surface acoustic wave devices can be used to perform active or passive signal processing functions suitable for delay lines, attenuators, phase shifters, filters, amplifiers, oscillators, mixers, limiters, and the like. Such surface acoustic wave devices are often connected to other microelectronics components such as integrated circuits and RF generators to form assemblies for telecommunication, digital processing, and other applications using a means such as wire bonding or flip chip methods, each of which has disadvantages.

Surface acoustic wave devices include a transducer coupled to piezoelectric material that converts an electronic signal received from the transducer to an surface acoustic wave. Surface acoustic wave devices are often fabricated by forming the transducer on the surface of a piezoelectric material or over a substrate, which may or may not be piezoelectric.

Attempts have also been made to grow thin-films of piezoelectric material over a semiconductor substrate. Formation of such films on semiconductor substrates is desirable because it allows for the integration of acoustic wave devices with other microelectronics devices on a single substrate. However, thin films of piezoelectric material formed on semiconductor substrates are of lesser quality than bulk piezoelectric material because lattice mismatches between the host crystal, or semiconductor substrate, and the grown crystal, or piezoelectric material, cause the grown thin film of piezoelectric material to be of low crystalline quality. Furthermore, such thin films of piezoelectric material must be chosen from a set of materials that are compatible with the semiconductor substrate.

Generally, the desirable characteristics of surface acoustic wave devices increase as the crystallinity of the piezoelectric film increases. For example, the electromechanical coupling coefficient and the piezoelectric coefficient of a piezoelectric material in monocrystalline form is typically higher than that of the same material in polycrystalline or amorphous form. Accordingly, methods for forming monocrystalline piezoelectric films are desirable.

If a large area thin film of high quality monocrystalline piezoelectric material were available at low cost, a variety of surface acoustic wave devices can advantageously be fabricated using that film at a low cost compared to the cost of fabricating such devices on a bulk wafer of the piezoelectric material or on an epitaxial film of such material on an expensive sapphire substrate. In addition, if thin films of high quality monocrystalline piezoelectric material and compound semiconductor material can be realized on a bulk wafer such as a silicon wafer, an integrated device structure can be achieved that advantageously uses the properties of both the compound semiconductor material and the piezoelectric material. Modular technologies such as low temperature co-fired ceramic (LTCC) technologies can combine diverse substrates, but the overall size of such devices cannot be minimized, as compared to the aggregate size of discrete devices, due to interface requirements for wire bonding and the like.

Accordingly, a need also exists for an integrated circuit having at least one surface acoustic wave device in and over a high quality monocrystalline piezoelectric layer over another monocrystalline layer such as a semiconductor substrate. A need also exists for a process for fabricating such an integrated circuit.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a high resolution Transmission Electron Micrograph of a structure including a monocrystalline accommodating buffer layer;

FIG. 6 illustrates an x-ray diffraction spectrum of a structure including a monocrystalline accommodating buffer layer;

FIG. 7 illustrates a high resolution Transmission Electron Micrograph of a structure including an amorphous oxide layer;

FIG. 8 illustrates an x-ray diffraction spectrum of a structure including an amorphous oxide layer;

FIGS. 9-12 illustrate schematically, in cross-section, the formation of a device structure in accordance with another embodiment of the invention;

FIGS. 13 and 14 illustrate schematically, in cross section, device structures that can be used in accordance with various embodiments of the invention;

FIGS. 15-19 include illustrations of cross-sectional views of a portion of an integrated circuit that includes a compound semiconductor portion, a bipolar portion, and a MOS portion in accordance with what is shown herein;

FIGS. 20, 21, and 22 illustrate schematically, in cross section, semiconductor structures in accordance with various embodiments of the invention;

FIG. 23 illustrates a top view of a surface acoustic wave transducer in accordance with an embodiment of the invention;

FIG. 24 illustrates a cross-sectional view of the surface acoustic wave transducer of FIG. 23 in accordance with an embodiment of the invention;

FIG. 25 illustrates another cross-sectional view of the surface acoustic wave transducer of FIG. 23 in accordance with an embodiment of the invention;

FIG. 26 illustrates a top view of a portion of a surface acoustic wave device in accordance with an embodiment of the invention;

FIG. 27 illustrates a flow chart of a process for fabricating a semiconductor structure and acoustic wave device in accordance with an embodiment of the invention;

FIGS. 28 through 33 illustrate schematically, in cross section, various integrated circuits in accordance with various embodiments of the invention; and

FIG. 34 illustrates a flow chart of a process for fabricating an integrated circuit in accordance with an embodiment of the invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

Furthermore, the terms first, second, and the like in the description and in the claims, if any, are used for distinguishing between similar elements and not necessarily for describing a sequential or chronological order. It is further understood that the terms so used are interchangeable under appropriate circumstances such that the embodiments of the invention described herein are, for example, capable of operation in other sequences than illustrated or otherwise described herein.

Moreover, the terms front, back, top, bottom, over, under, and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than illustrated or otherwise described herein.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a monocrystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and monocrystalline material layer 26. As will be explained more fully below, the template layer helps to initiate the growth of the monocrystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Substrate 22 may also be, for example, silicon-on-insulator (SOI), where a thin layer of silicon is on top of an insulating material such as silicon oxide or glass. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in monocrystalline material layer 26 which may comprise a semiconductor material, a compound semiconductor material, or another type of material such as a metal or a non-metal.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied monocrystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and other perovskite oxide materials, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for monocrystalline material layer 26 can be selected, as desired, for a particular structure or application. For example, the monocrystalline material of layer 26 may comprise a compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), mixed II-VI compounds, Group IV and VI elements (IV-VI semiconductor compounds), mixed IV-VI compounds, Group IV elements (Group IV semiconductors), and mixed Group IV compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), silicon (Si), germanium (Ge), silicon germanium (SiGe), silicon germanium carbide (SiGeC), and the like. However, monocrystalline material layer 26 may also comprise other semiconductor materials, metals, or non-metal materials which are used in the formation of semiconductor structures, devices and/or integrated circuits.

Appropriate materials for template 30 are discussed below. Suitable template materials chemically bond to the surface of the accommodating buffer layer 24 at selected sites and provide sites for the nucleation of the epitaxial growth of monocrystalline material layer 26. When used, template layer 30 has a thickness ranging from about 1 to about 10 monolayers.

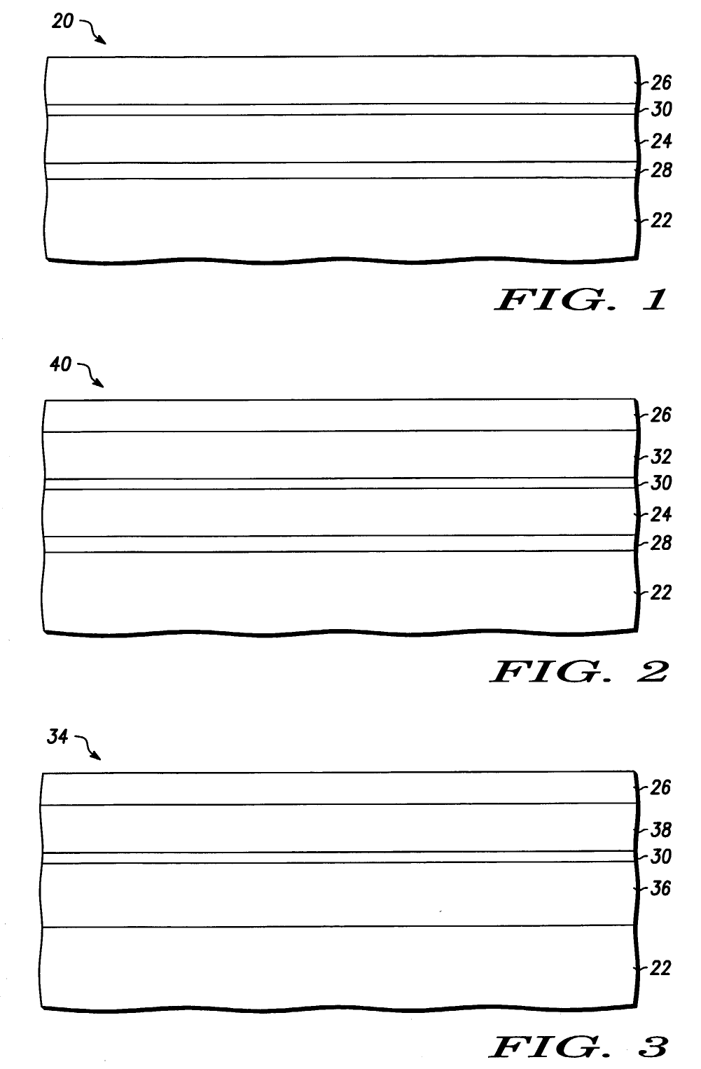

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and monocrystalline material layer 26. Specifically, the additional buffer layer 32 is positioned between template layer 30 and the overlying layer of monocrystalline material. The additional buffer layer, formed of a semiconductor or compound semiconductor material when the monocrystalline material layer 26 comprises a semiconductor or compound semiconductor material, serves to provide a lattice compensation when the lattice constant of the accommodating buffer layer cannot be adequately matched to the overlying monocrystalline semiconductor or compound semiconductor material layer.

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional monocrystalline layer 38.

As explained in greater detail below, amorphous layer 36 may be formed by first forming an accommodating buffer layer and an amorphous interface layer in a similar manner to that described above. Monocrystalline layer 38 is then formed (by epitaxial growth) overlying the monocrystalline accommodating buffer layer. The accommodating buffer layer may then be optionally exposed to an anneal process to convert at least a portion of the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional monocrystalline layer 26 (subsequent to layer 38 formation) relieves stresses between layers 22 and 38 and provides strain relief for subsequent processing—e.g., monocrystalline material layer 26 formation.

The processes previously described above in connection with FIGS. 1 and 2 are adequate for growing monocrystalline material layers over a monocrystalline substrate. However, the process described in connection with FIG. 3, which includes transforming at least a portion of a monocrystalline accommodating buffer layer to an amorphous oxide layer, may be better for growing monocrystalline material layers because it allows any strain in layer 26 to relax.

Additional monocrystalline layer 38 may include any of the materials described throughout this application in connection with either of monocrystalline material layer 26 or additional buffer layer 32. For example, when monocrystalline material layer 26 comprises a semiconductor or compound semiconductor material, layer 38 may include monocrystalline Group IV, monocrystalline compound semiconductor materials, or other monocrystalline materials including oxides and nitrides.

In accordance with one embodiment of the present invention, additional monocrystalline layer 38 serves as an anneal cap during layer 36 formation and as a template for subsequent monocrystalline layer 26 formation. Accordingly, layer 38 is preferably thick enough to provide a suitable template for layer 26 growth (at least one monolayer) and thin enough to allow layer 38 to form as a substantially defect free monocrystalline material.

In accordance with another embodiment of the invention, additional monocrystalline layer 38 comprises monocrystalline material (e.g., a material discussed above in connection with monocrystalline layer 26) that is thick enough to form devices within layer 38. In this case, a semiconductor structure in accordance with the present invention does not include monocrystalline material layer 26. In other words, the semiconductor structure in accordance with this embodiment only includes one monocrystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate typically (100) oriented. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr₂Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The lattice structure of the resulting crystalline oxide exhibits a substantially 45 degree rotation with respect to the substrate silicon lattice structure. The accommodating buffer layer can have a thickness of about 2 to about 100 nanometers (nm) and preferably has a thickness of about 5 nm. In general, it is desired to have an accommodating buffer layer thick enough to isolate the monocrystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, monocrystalline material layer 26 is a compound semiconductor layer of gallium arsenide (GaAs) or aluminum gallium arsenide (AlGaAs) having a thickness of about 1 nm to about 100 micrometers (μm) and preferably a thickness of about 0.5 μm to 10 μm. The thickness generally depends on the application for which the layer is being prepared. To facilitate the epitaxial growth of the gallium arsenide or aluminum gallium arsenide on the monocrystalline oxide, a template layer is formed by depositing a surfactant layer comprising one element of the compound semiconductor layer to react with the surface of the oxide layer that has been previously capped. The capping layer is preferably up to 3 monolayers of Sr—O, Ti—O, strontium or titanium. The template layer is preferably of Sr—Ga, Ti—Ga, Ti—As, Ti—O—As, Ti—O—Ga, Sr—O—As, Sr—Ga—O, Sr—Al—O, or Sr—Al. The thickness of the template layer is preferably about 0.5 to about 10 monolayers, and preferably about 0.5-3 monolayers. By way of a preferred example 0.5-3 monolayers of Ga deposited on a capped Sr—O terminated surface have been illustrated to successfully grow GaAs layers. The resulting lattice structure of the compound semiconductor material exhibits a substantially 45 degree rotation with respect to the accommodating buffer layer lattice structure.

### EXAMPLE 2

In accordance with a further embodiment of the invention, monocrystalline substrate 22 is a silicon substrate as described above. The accommodating buffer layer is a monocrystalline oxide of strontium or barium zirconate or hafnate in a cubic or orthorhombic phase with an amorphous intermediate layer of silicon oxide formed at the interface between the silicon substrate and the accommodating buffer layer. The accommodating buffer layer can have a thickness of about 2-100 nm and preferably has a thickness of at least 4 nm to ensure adequate crystalline and surface quality and is formed of monocrystalline SrZrO₃, BaZrO₃, SrHfO₃, BaSnO₃ or BaHfO₃. For example, a monocrystalline oxide layer of BaZrO₃ can grow at a temperature of about 700 degrees C. The lattice structure of the resulting crystalline oxide exhibits a substantially 45 degree rotation with respect to the substrate silicon lattice structure.

An accommodating buffer layer formed of these zirconate or hafnate materials is suitable for the growth of a monocrystalline material layer which comprises compound semiconductor materials in an indium phosphide (InP) system. In this system, the compound semiconductor material can be, for example, indium phosphide (InP), indium gallium arsenide (InGaAs), aluminum indium arsenide, (AlInAs), or aluminum gallium indium arsenic phosphide (AlGaInAsP), having a thickness of about 1.0 nm to 10 μm. A suitable template for this structure is about 0.5-10 monolayers of one of a material M-N and a material M—O—N, wherein M is selected from at least one of Zr, Hf, Ti, Sr, and Ba; and N is selected from at least one of As, P, Ga, Al, and In.

Alternatively, the template may comprise 0.5-10 monolayers of gallium (Ga), aluminum (Al), indium (In), or a combination of gallium, aluminum or indium, zirconium-arsenic (Zr—As), zirconium-phosphorus (Zr—P), hafnium-arsenic (Hf—As), hafnium-phosphorus (Hf—P), strontium-oxygen-arsenic (Sr—O—As), strontium-oxygen-phosphorus (Sr—O—P), barium-oxygen-arsenic (Ba—O—As), indium-strontium-oxygen (In—Sr—O), or barium-oxygen-phosphorus (Ba—O—P), and preferably 0.5-2 monolayers of one of these materials. By way of an example, for a barium zirconate accommodating buffer layer, the surface is terminated with 0.5-2 monolayers of zirconium followed by deposition of 0.5-2 monolayers of arsenic to form a Zr—As template. A monocrystalline layer of the compound semiconductor material from the indium phosphide system is then grown on the template layer. The resulting lattice structure of the compound semiconductor material exhibits a substantially 45 degree rotation with respect to the accommodating buffer layer lattice structure and a lattice mismatch between the buffer layer and (100) oriented InP of less than 2.5%, and preferably less than about 1.0%.

### EXAMPLE 3

In accordance with a further embodiment of the invention, a structure is provided that is suitable for the growth of an epitaxial film of a monocrystalline material comprising a II-VI material overlying a silicon substrate. The substrate is preferably a silicon wafer as described above. A suitable accommodating buffer layer material is SrₓBa₁₋ₓTiO₃, where x ranges from 0 to 1, having a thickness of about 2-100 nm and preferably a thickness of about 3-10 nm. The lattice structure of the resulting crystalline oxide exhibits a substantially 45 degree rotation with respect to the substrate silicon lattice structure. Where the monocrystalline layer comprises a compound semiconductor material, the II-VI compound semiconductor material can be, for example, zinc selenide (ZnSe) or zinc sulfur selenide (ZnSSe). A suitable template for this material system includes 0.5-10 monolayers of zinc-oxygen (Zn—O) followed by 0.5-2 monolayers of an excess of zinc followed by the selenidation of zinc on the surface. Alternatively, a template can be, for example, 0.5-10 monolayers of strontium-sulfur (Sr—S) followed by the ZnSSe.

### EXAMPLE 4

This embodiment of the invention is an example of structure 40 illustrated in FIG. 2. Substrate 22, accommodating buffer layer 24, and monocrystalline material layer 26 can be similar to those described in example 1. In addition, an additional buffer layer 32 serves to alleviate any strains that might result from a mismatch of the crystal lattice of the accommodating buffer layer and the lattice of the monocrystalline material. Buffer layer 32 can be a layer of germanium or a GaAs, an aluminum gallium arsenide (AlGaAs), an indium gallium phosphide (InGaP), an aluminum gallium phosphide (AlGaP), an indium gallium arsenide (InGaAs), an aluminum indium phosphide (AlInP), a gallium arsenide phosphide (GaAsP), or an indium gallium phosphide (InGaP) strain compensated superlattice. In accordance with one aspect of this embodiment, buffer layer 32 includes a GaAsₓP₁₋ₓ, superlattice, wherein the value of x ranges from 0 to 1. In accordance with another aspect, buffer layer 32 includes an In_{y}Ga_{1-y}P superlattice, wherein the value of y ranges from 0 to 1. By varying the value of x or y, as the case may be, the lattice constant is varied from bottom to top across the superlattice to create a substantial (i.e., effective) match between lattice constants of the underlying oxide and the overlying monocrystalline material which in this example is a compound semiconductor material. The compositions of other compound semiconductor materials, such as those listed above, may also be similarly varied to manipulate the lattice constant of layer 32 in a like manner. The superlattice can have a thickness of about 50-500 nm and preferably has a thickness of about 100-200 nm. The superlattice period can have a thickness of about 2-15 nm, preferably 2-10 nm. The template for this structure can be the same as that described in example 1. Alternatively, buffer layer 32 can be a layer of monocrystalline germanium having a thickness of 1-50 nm and preferably having a thickness of about 2-20 nm. In using a germanium buffer layer, a template layer of either germanium-strontium (Ge—Sr) or germanium-titanium (Ge—Ti) having a thickness of about 0.5-2 monolayers can be used as a nucleating site for the subsequent growth of the monocrystalline material layer which in this example is a compound semiconductor material. The formation of the oxide layer is capped with either a 0.5-2 monolayer of strontium or a 0.5-2 monolayer of titanium to act as a nucleating site for the subsequent deposition of the monocrystalline germanium. The layer of strontium or titanium provides a nucleating site to which the first monolayer of germanium can bond.

### EXAMPLE 5

This example also illustrates materials useful in a structure 40 as illustrated in FIG. 2. Substrate material 22, accommodating buffer layer 24, monocrystalline material layer 26 and template layer 30 can be the same as those described above in example 2. In addition, additional buffer layer 32 is inserted between the accommodating buffer layer and the overlying monocrystalline material layer. The buffer layer, a further monocrystalline material which in this instance comprises a semiconductor material, can be, for example, a graded layer of indium gallium arsenide (InGaAs) or indium aluminum arsenide (InAlAs). In accordance with one aspect of this embodiment, additional buffer layer 32 includes InGaAs, in which the indium composition varies from 0% at the monocrystalline material layer 26 to about 50% at the accommodating buffer layer 24. The additional buffer layer 32 preferably has a thickness of about 10-30 nm. Varying the composition of the buffer layer from GaAs to InGaAs serves to provide an effective (i.e. substantial) lattice match between the underlying monocrystalline oxide material and the overlying layer of monocrystalline material which in this example is a compound semiconductor material. Such a buffer layer is especially advantageous if there is a lattice mismatch between accommodating buffer layer 24 and monocrystalline material layer 26.

### EXAMPLE 6

This example provides exemplary materials useful in structure 34, as illustrated in FIG. 3. Substrate material 22, template layer 30, and monocrystalline material layer 26 may be the same as those described above in connection with example 1.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of monocrystalline material comprising layer 26, and the like. In accordance with one exemplary aspect of the present embodiment, layer 36 thickness is about 1 nm to about 100 nm, preferably about 1-10 nm, and more preferably about 3-5 nm.

Layer 38 comprises a monocrystalline material that can be grown epitaxially over a monocrystalline oxide material such as material used to form accommodating buffer layer 24. In accordance with one embodiment of the invention, layer 38 includes the same materials as those comprising layer 26. For example, if layer 26 includes GaAs, layer 38 also includes GaAs. However, in accordance with other embodiments of the present invention, layer 38 may include materials different from those used to form layer 26. In accordance with one exemplary embodiment of the invention, layer 38 is about 1 nm to about 500 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

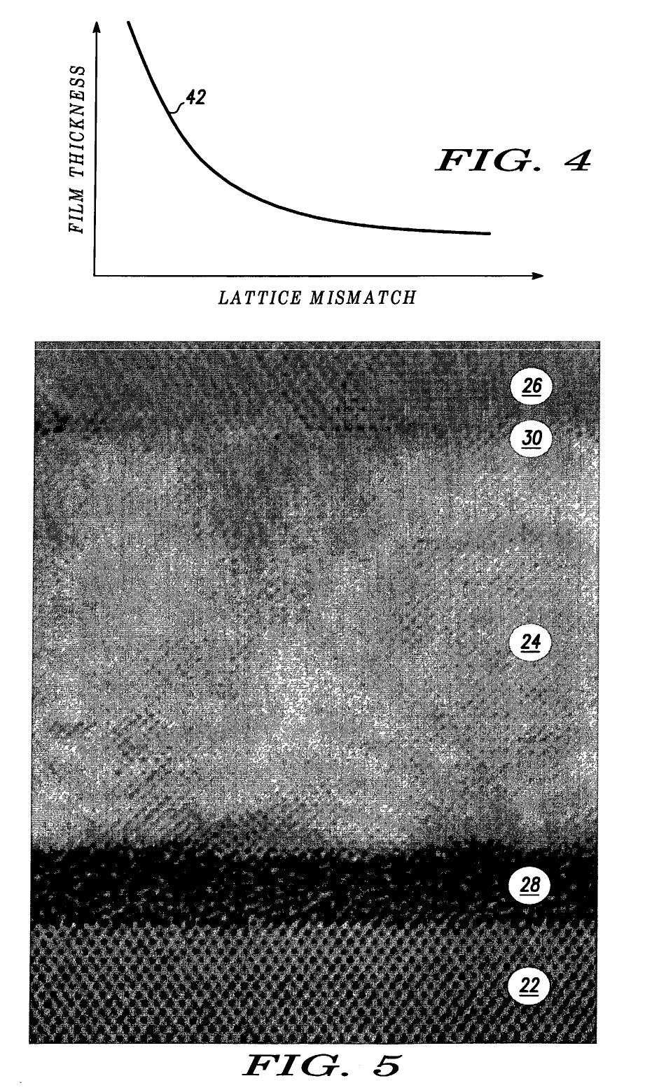

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is typically a (100) oriented monocrystalline silicon wafer and accommodating buffer layer 24 is a layer of strontium barium titanate. Substantial (i.e., effective) matching of lattice constants between these two materials is achieved by rotating the crystal orientation of the titanate material by approximately 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, layer 26 is a layer of epitaxially grown monocrystalline material and that crystalline material is also characterized by a crystal lattice constant and a crystal orientation. In accordance with one embodiment of the invention, the lattice constant of layer 26 differs from the lattice constant of substrate 22. To achieve high crystalline quality in this epitaxially grown monocrystalline layer, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal. For example, if the grown crystal is gallium arsenide, aluminum gallium arsenide, zinc selenide, or zinc sulfur selenide and the accommodating buffer layer is monocrystalline SrₓBa₁₋ₓTiO₃, substantial matching of crystal lattice constants of the two materials is achieved, wherein the crystal orientation of the grown layer is rotated by substantially 45° with respect to the orientation of the host monocrystalline oxide. Similarly, if the host material is a strontium or barium zirconate or a strontium or barium hafnate or barium tin oxide and the compound semiconductor layer is indium phosphide or gallium indium arsenide or aluminum indium arsenide, substantial matching of crystal lattice constants can be achieved by rotating the orientation of the grown crystal layer by substantially 45° with respect to the host oxide crystal. In some instances, a crystalline semiconductor buffer layer 32 between the host oxide and the grown monocrystalline material layer 26 can be used to reduce strain in the grown monocrystalline material layer that might result from small differences in lattice constants. Better crystalline quality in the grown monocrystalline material layer can thereby be achieved.

The following example illustrates a process, in accordance with one embodiment of the invention, for fabricating a semiconductor structure such as the structures depicted in FIGS. 1-3. The process starts by providing a monocrystalline semiconductor substrate comprising silicon or germanium. In accordance with a preferred embodiment of the invention, the semiconductor substrate is a silicon wafer having a (100) orientation. The substrate is oriented on axis or, at most, about 6° off axis, and preferably misoriented 1-3° off axis toward the [110] direction. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate. The following process is preferably carried out by molecular beam epitaxy (MBE), although other epitaxial processes may also be used in accordance with the present invention. The native oxide can be removed by first thermally depositing a thin layer (preferably 1-3 monolayers) of strontium, barium, a combination of strontium and barium, or other alkaline earth metals or combinations of alkaline earth metals in an MBE apparatus. In the case where strontium is used, the substrate is then heated to a temperature above 720° C. as measured by an optical pyrometer to cause the strontium to react with the native silicon oxide layer. The strontium serves to reduce the silicon oxide to leave a silicon oxide-free surface. The resultant surface may exhibit an ordered (2×1) structure. If an ordered (2×1) structure has not been achieved at this stage of the process, the structure may be exposed to additional strontium until an ordered (2×1) structure is obtained. The ordered (2×1) structure forms a template for the ordered growth of an overlying layer of a monocrystalline oxide. The template provides the necessary chemical and physical properties to nucleate the crystalline growth of an overlying layer.

It is understood that precise measurement of actual temperatures in MBE equipment, as well as other processing equipment, is difficult, and is commonly accomplished by the use of a pyrometer or by means of a thermocouple placed in close proximity to the substrate. Calibrations can be performed to correlate the pyrometer temperature reading to that of the thermocouple. However, neither temperature reading is necessarily a precise indication of actual substrate temperature. Furthermore, variations may exist when measuring temperatures from one MBE system to another MBE system. For the purpose of this description, typical pyrometer temperatures will be used, and it should be understood that variations may exist in practice due to these measurement difficulties.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of above 720° C. At this temperature a solid state reaction takes place between the strontium oxide and the native silicon oxide causing the reduction of the native silicon oxide and leaving an ordered (2×1) structure on the substrate surface. If an ordered (2×1) structure has not been achieved at this stage of the process, the structure may be exposed to additional strontium until an ordered (2×1) structure is obtained. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-600° C., preferably 350′-550° C., and a layer of strontium titanate is grown on the template layer by molecular beam epitaxy. The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.1-0.8 nm per minute, preferably 0.3-0.5 nm per minute. After initiating growth of the strontium titanate, the partial pressure of oxygen is increased above the initial minimum value. The stoichiometry of the titanium can be controlled during growth by monitoring RHEED patterns and adjusting the titanium flux. The overpressure of oxygen causes the growth of an amorphous silicon oxide layer at the interface between the underlying substrate and the strontium titanate layer. This step may be applied either during or after the growth of the strontium titanate layer. The growth of the amorphous silicon oxide layer results from the diffusion of oxygen through the strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired monocrystalline material. For example, for the subsequent growth of a monocrystalline compound semiconductor material layer of gallium arsenide, the MBE growth of the strontium titanate monocrystalline layer can be capped by terminating the growth with up to 2 monolayers of titanium, up to 2 monolayers of strontium, up to 2 monolayers of titanium-oxygen or with up to 2 monolayers of strontium-oxygen. Following the formation of this capping layer, arsenic is deposited to form a Ti—As bond, a Ti—O—As bond or a Sr—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, 0.5-3 monolayers of gallium can be deposited on the capping layer to form a Sr—O—Ga bond, or a Ti—O—Ga bond, and arsenic is subsequently introduced with the gallium to form the GaAs.

FIG. 5 is a high resolution Transmission Electron Micrograph (TEM) of semiconductor material manufactured in accordance with one embodiment of the present invention. Single crystal SrTiO₃ accommodating buffer layer 24 was grown epitaxially on silicon substrate 22. During this growth process, amorphous interfacial layer 28 is formed, which relieves strain due to lattice mismatch. GaAs compound semiconductor layer 26 was then grown epitaxially using template layer 30.

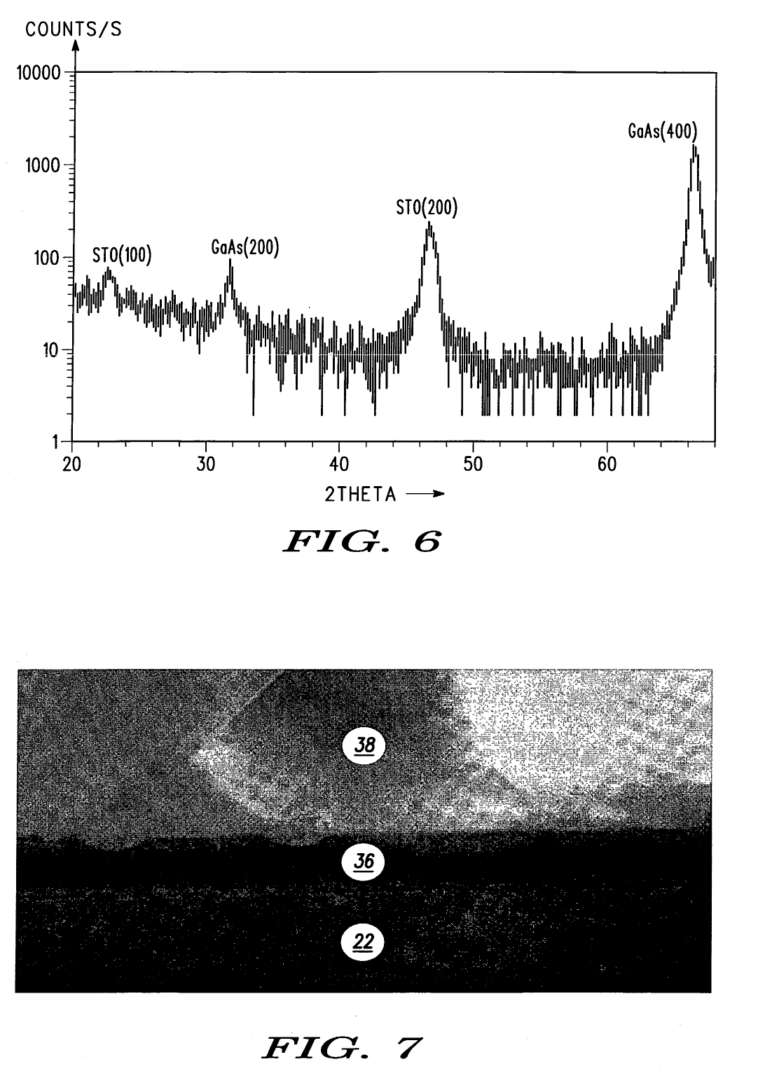

FIG. 6 illustrates an x-ray diffraction spectrum taken on a structure including GaAs monocrystalline layer 26 comprising GaAs grown on silicon substrate 22 using accommodating buffer layer 24. The peaks in the spectrum indicate that both the accommodating buffer layer 24 and GaAs compound semiconductor layer 26 are single crystal and (100) oriented.

The structure illustrated in FIG. 2 can be formed by the process discussed above with the addition of an additional buffer layer deposition step. The additional buffer layer 32 is formed overlying the template layer 30 before the deposition of the monocrystalline material layer 26. If the additional buffer layer 32 is a monocrystalline material comprising a compound semiconductor superlattice, such a superlattice can be deposited, by MBE for example, on the template 30 described above. If instead, the additional buffer layer is a monocrystalline material layer comprising a layer of germanium, the process above is modified to cap the first buffer layer of strontium titanate with a final template layer of either strontium or titanium and then by depositing germanium to react with the strontium or titanium. The germanium buffer layer can then be deposited directly on this template.

Structure 34, illustrated in FIG. 3, may be formed by growing an accommodating buffer layer 24, forming an amorphous oxide layer 28 over substrate 22, and growing semiconductor layer 38 over the accommodating buffer layer, as described above. The accommodating buffer layer 24 and the amorphous oxide layer 28 are then exposed to a higher temperature anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer 24, the amorphous oxide layer 28, and monocrystalline layer 38 to a rapid thermal anneal process with a peak temperature of about 700° C. to about 1000° C. (actual temperature) and a process time of about 5 seconds to about 20 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 38 may be required to prevent degradation of layer 38 during the anneal process. For example, when layer 38 includes GaAs, the anneal environment preferably includes an overpressure of arsenic to mitigate degradation of layer 38. Alternately, an appropriate anneal cap, such as silicon nitride, may be utilized to prevent the degradation of layer 38 during the anneal process with the anneal cap being removed after the annealing process.

As noted above, layer 38 of structure 34 may include any materials suitable for either of layers 32 or 26. Accordingly, any deposition or growth methods described in connection with either layer 32 or 26 may be employed to deposit layer 38.

FIG. 7 is a high resolution TEM of semiconductor material manufactured in accordance with the embodiment of the invention illustrated in FIG. 3. In accordance with this embodiment, a single crystal SrTiO₃ accommodating buffer layer was grown epitaxially on silicon substrate 22. During this growth process, an amorphous interfacial layer forms as described above. Next, additional monocrystalline layer 38 comprising a compound semiconductor layer of GaAs is formed above the accommodating buffer layer and the accommodating buffer layer is exposed to an anneal process to form amorphous oxide layer 36.

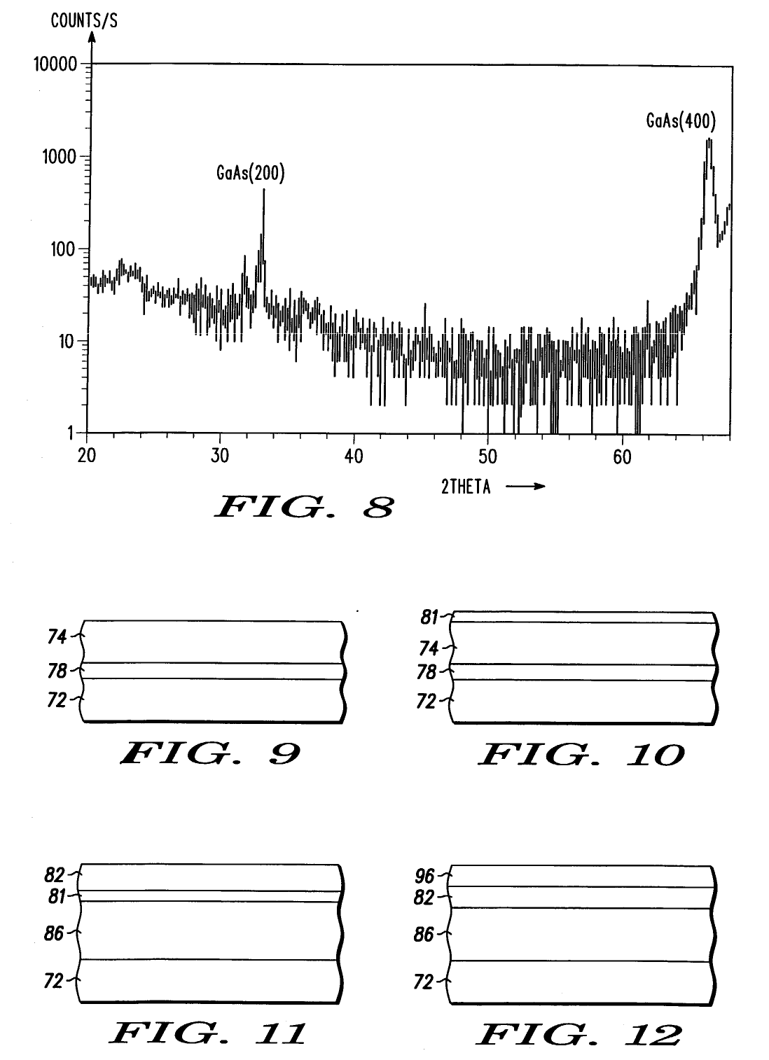

FIG. 8 illustrates an x-ray diffraction spectrum taken on a structure including additional monocrystalline layer 38 comprising a GaAs compound semiconductor layer and amorphous oxide layer 36 formed on silicon substrate 22. The peaks in the spectrum indicate that GaAs compound semiconductor layer 38 is single crystal and (100) oriented and the lack of peaks around 40 to 50 degrees indicates that layer 36 is amorphous.

The process described above illustrates a process for forming a semiconductor structure including a silicon substrate, an overlying oxide layer, and a monocrystalline material layer comprising a gallium arsenide compound semiconductor layer by the process of molecular beam epitaxy. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, niobates, alkaline earth metal tin-based perovskites, lanthanum aluminate, lanthanum scandium oxide, and gadolinium oxide can also be grown. Further, by a similar process such as MBE, other monocrystalline material layers comprising other III-V, I-VI, and IV-VI monocrystalline compound semiconductors, semiconductors, metals and non-metals can be deposited overlying the monocrystalline oxide accommodating buffer layer.

Each of the variations of monocrystalline material layer and monocrystalline oxide accommodating buffer layer uses an appropriate template for initiating the growth of the monocrystalline material layer. For example, if the accommodating buffer layer is an alkaline earth metal zirconate, the oxide can be capped by a thin layer of zirconium. The deposition of zirconium can be followed by the deposition of arsenic or phosphorus to react with the zirconium as a precursor to depositing indium gallium arsenide, indium aluminum arsenide, or indium phosphide, respectively. Similarly, if the monocrystalline oxide accommodating buffer layer is an alkaline earth metal hafnate, the oxide layer can be capped by a thin layer of hafnium. The deposition of hafnium is followed by the deposition of arsenic or phosphorous to react with the hafnium as a precursor to the growth of an indium gallium arsenide, indium aluminum arsenide, or indium phosphide layer, respectively. In a similar manner, strontium titanate can be capped with a layer of strontium or strontium and oxygen, and barium titanate can be capped with a layer of barium or barium and oxygen. Each of these depositions can be followed by the deposition of arsenic or phosphorus to react with the capping material to form a template for the deposition of a monocrystalline material layer comprising compound semiconductors such as indium gallium arsenide, indium aluminum arsenide, or indium phosphide.

Single crystal silicon has 4-fold symmetry. That is, its structure is essentially the same as it is rotated in 90 degree steps in the plane of the (100) surface. Likewise, strontium titanate and many other oxides have a 4-fold symmetry. On the other hand, GaAs and related compound semiconductors have a 2-fold symmetry. The 0 degree and 180 degree rotations of the 2-fold symmetry are not the same as the 90 degree and 270 degree rotations of the 4-fold symmetry. If GaAs is nucleated upon strontium titanate at multiple locations on the surface, two different phases are produced. As the material continues to grow, the two phases meet and form anti-phase domains. These anti-phase domains can have an adverse effect upon certain types of devices, particularly minority carrier devices like lasers and light emitting diodes.

In accordance with one embodiment of the present invention, in order to provide for the formation of high quality monocrystalline compound semiconductor material, the starting substrate is off-cut or misoriented from the ideal (100) orientation by 0.5 to 6 degrees in any direction, and preferably 1 to 2 degrees toward the [110] direction. This offcut provides for steps or terraces on the silicon surface and it is believed that these substantially reduce the number of anti-phase domains in the compound semiconductor material, in comparison to a substrate having an offcut near 0 degrees or off cuts larger than 6 degrees. The greater the amount of off-cut, the closer the steps and the smaller the terrace widths become. At very small angles, nucleation occurs at other than the step edges, decreasing the size of single phase domains. At high angles, smaller terraces decrease the size of single phase domains. Growing a high quality oxide, such as strontium titanate, upon a silicon surface causes surface features to be replicated on the surface of the oxide. The step and terrace surface features are replicated on the surface of the oxide, thus preserving directional cues for subsequent growth of compound semiconductor material. Because the formation of the amorphous interface layer occurs after the nucleation of the oxide has begun, the formation of the amorphous interface layer does not disturb the step structure of the oxide.

After the growth of an appropriate accommodating buffer layer, such as strontium titanate or other materials as described earlier, a template layer is used to promote the proper nucleation of compound semiconductor material. In accordance with one embodiment, the strontium titanate is capped with up to 2 monolayers of SrO. The template layer 30 for the nucleation of GaAs is formed by raising the substrate to a temperature in the range of 540 to 630 degrees and exposing the surface to gallium. The amount of gallium exposure is preferably in the range of 0.5 to 5 monolayers. It is understood that the exposure to gallium does not imply that all of the material will actually adhere to the surface. Not wishing to be bound by theory, it is believed that the gallium atoms adhere more readily at the exposed step edges of the oxide surface. Thus, subsequent growth of gallium arsenide preferentially forms along the step edges and prefer an initial alignment in a direction parallel to the step edge, thus forming predominantly single domain material. Other materials besides gallium may also be utilized in a similar fashion, such as aluminum and indium or a combination thereof.

After the deposition of the template, a compound semiconductor material such as gallium arsenide may be deposited. The arsenic source shutter is preferably opened prior to opening the shutter of the gallium source. Small amounts of other elements may also be deposited simultaneously to aid nucleation of the compound semiconductor material layer. For example, aluminum may be deposited to form AlGaAs. As noted above, layer 38, illustrated in FIG. 3, comprises a monocrystalline material that can be grown epitaxially over a monocrystalline oxide material, such as material used to form accommodating buffer layer 24. In accordance with one embodiment of the invention, layer 38 includes materials different from those used to form layer 26. For example, in a preferred embodiment, layer 38 includes AlGaAs, which is deposited as a nucleation layer at a relatively slow growth rate. For example, the growth rate of layer 38 of AlGaAs can be approximately 0.10-0.5 μm/hr. In this case, growth can be initiated by first depositing As on template layer 30, followed by deposition of aluminium and gallium. Deposition of the nucleation layer generally is accomplished at about 300-600° C, and preferably 400-500° C. In accordance with one exemplary embodiment of the invention, the nucleation layer is about 1 nm to about 500 nm thick, and preferably 5 nm to about 50 nm. In this case, the aluminum source shutter is preferably opened prior to opening the gallium source shutter. The amount of aluminum is preferably in the range from 0 to 50% (expressed as a percentage of the aluminum content in the AlGaAs layer), and is most preferably about 15-25%. Other materials, such as InGaAs, could also be used in a similar fashion. Once the growth of compound semiconductor material is initiated, other mixtures of compound semiconductor materials can be grown with various compositions and various thicknesses as required for various applications. For example, a thicker layer of GaAs may be grown on top of the AlGaAs layer to provide a semi-insulating buffer layer prior to the formation of device layers.

The quality of the compound semiconductor material can be improved by including one or more in-situ anneals at various points during the growth. The growth is interrupted, and the substrate is raised to a temperature of between 500°-650° C., and preferably about 550°-600° C. The anneal time depends on the temperature selected, but for an anneal of about 550° C., the length of time is preferably about 15 minutes. The anneal can be performed at any point during the deposition of the compound semiconductor material, but preferably is performed when there is 50 nm to 500 nm of compound semiconductor material deposited. Additional anneals may also be done, depending on the total thickness of material being deposited.

In accordance with one embodiment, monocrystalline material layer 26 is GaAs. Layer 26 may be deposited on layer 24 at various rates, which may vary from application to application; however in a preferred embodiment, the growth rate of layer 26 is about 0.2 to 1.0 lm/hr. The temperature at which layer 26 is grown may also vary, but in one embodiment, layer 26 is grown at a temperature of about 300°-600° C. and preferably about 350°-500° C.

Turning now to FIGS. 9-12, the formation of a device structure in accordance with still another embodiment of the invention is illustrated in cross-section. This embodiment utilizes the formation of a compliant substrate which relies on the epitaxial growth of single crystal oxides on silicon followed by the epitaxial growth of single crystal silicon onto the oxide.

An accommodating buffer layer 74 such as a monocrystalline oxide layer is first grown on a substrate layer 72, such as silicon, with an amorphous interface layer 78 as illustrated in FIG. 9. Monocrystalline oxide layer 74 may be comprised of any of those materials previously discussed with reference to layer 24 in FIGS. 1 and 2, while amorphous interface layer 78 is preferably comprised of any of those materials previously described with reference to the layer 28 illustrated in FIGS. 1 and 2. Substrate 72, although preferably silicon, may also comprise any of those materials previously described with reference to substrate 22 in FIGS. 1-3.

Next, a silicon layer 81 is deposited over monocrystalline oxide layer 74 via MBE, CVD, MOCVD, MEE, ALE, PVD, CSD, PLD, or the like as illustrated in FIG. 10 with a thickness of a few tens of nanometers but preferably with a thickness of about 5 nm. Monocrystalline oxide layer 74 preferably has a thickness of about 2 to 10 nm.

Rapid thermal annealing is then conducted in the presence of a carbon source such as acetylene or methane, for example at a temperature within a range of about 800° C to 1000° C. to form capping layer 82 and silicate amorphous layer 86. However, other suitable carbon sources may be used as long as the rapid thermal annealing step functions to amorphize the monocrystalline oxide layer 74 into a silicate amorphous layer 86 and carbonize the top silicon layer 81 to form capping layer 82 which in this example would be a silicon carbide (SiC) layer as illustrated in FIG. 11. The formation of amorphous layer 86 is similar to the formation of layer 36 illustrated in FIG. 3 and may comprise any of those materials described with reference to layer 36 in FIG. 3 but the preferable material will be dependent upon the capping layer 82 used for silicon layer 81.

Finally, as shown in FIG. 12, a compound semiconductor layer 96, such as gallium nitride (GaN), is grown over the SiC surface by way of MBE, CVD, MOCVD, MEE, ALE, PVD, CSD, PLD, or the like to form a high quality compound semiconductor material for device formation. More specifically, the deposition of GaN and GaN based systems such as GaInN and AlGaN will result in the formation of dislocation nets confined at the silicon/amorphous region. The resulting nitride containing compound semiconductor material may comprise elements from groups III, IV and V of the periodic table and is defect free.

Although GaN has been grown on SiC substrate in the past, this embodiment of the invention possesses a one step formation of the compliant substrate containing a SiC top surface and an amorphous layer on a Si surface. More specifically, this embodiment of the invention uses an intermediate single crystal oxide layer that is amorphized to form a silicate layer which adsorbs the strain between the layers. Moreover, unlike past use of a SiC substrate, this embodiment of the invention is not limited by wafer size which is usually less than 50 mm in diameter for prior art SiC substrates.

The monolithic integration of nitride containing semiconductor compounds containing group III-V nitrides and silicon devices can be used for high temperature and high power RF applications and optoelectronics. GaN systems have particular use in the photonic industry for the blue/green and UV light sources and detection. High brightness light emitting diodes (LEDs) and lasers may also be formed within the GaN system.

Clearly, those embodiments specifically describing structures having compound semiconductor portions and Group IV semiconductor portions are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline layers comprising semiconductor and compound semiconductor materials, as well as other material layers that are used to form those devices, with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming monocrystalline material layers over the wafer. In this manner, the wafer is essentially a “handle” wafer used during the fabrication of semiconductor electrical components within a monocrystalline layer overlying the wafer. Therefore, electrical components can be formed within semiconductor materials over a wafer of at least approximately 200 millimeters in diameter and possibly at least approximately 300 millimeters.

By the use of this type of substrate, the relatively inexpensive “handle” wafer overcomes the fragile nature of wafers fabricated of monocrystalline compound semiconductor or other monocrystalline material by placing the materials over a relatively more durable and easy to fabricate base substrate. Therefore, an integrated circuit can be formed such that all electrical components, and particularly all active electronic devices, can be formed within or using the monocrystalline material layer even though the substrate itself may include a different monocrystalline semiconductor material. Fabrication costs for compound semiconductor devices and other devices employing non-silicon monocrystalline materials should decrease because larger substrates can be processed more economically and more readily compared to the relatively smaller and more fragile substrates (e.g., conventional compound semiconductor wafers).

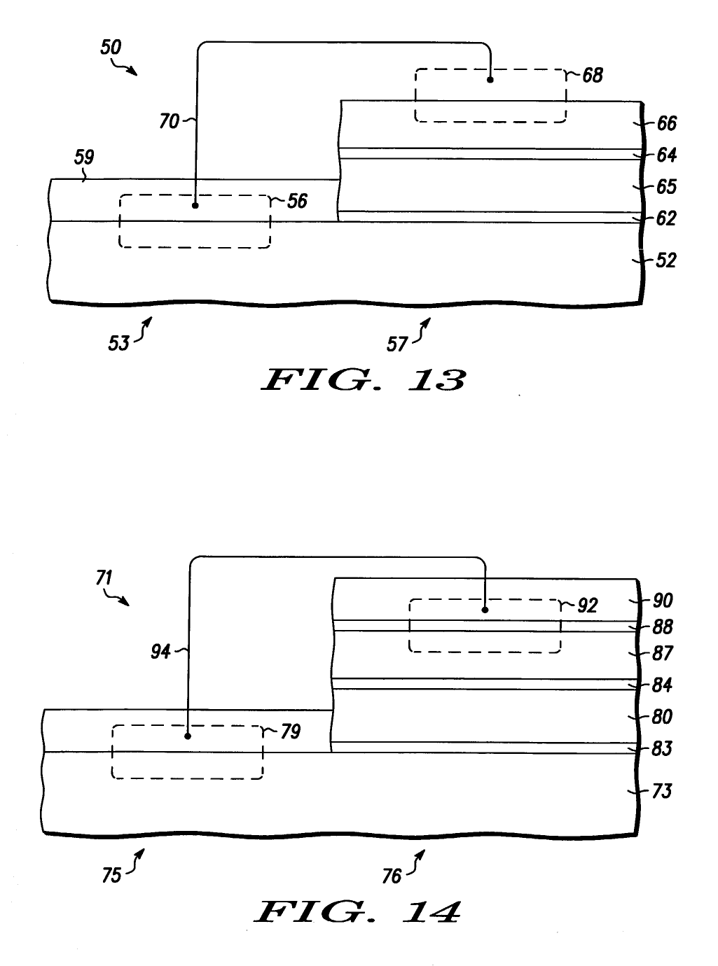

FIG. 13 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. A semiconductor component generally indicated by the dashed line 56 is formed, at least partially, in region 53. Semiconductor component 56 can be a resistor, a capacitor, an active electrical component such as a diode or a transistor, an optoelectric component such as a photo detector, or an integrated circuit such as a CMOS integrated circuit. For example, semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer (preferably 1-3 monolayers) of strontium or strontium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including strontium, titanium and oxygen are deposited onto the template layer to form the monocrystalline oxide layer. Initially during the deposition the partial pressure of oxygen is kept near the minimum necessary to fully react with the strontium and titanium to form a monocrystalline strontium titanate layer. The partial pressure of oxygen is then increased to provide an overpressure of oxygen and to allow oxygen to diffuse through the growing monocrystalline oxide layer. The oxygen diffusing through the strontium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a capping layer 64, which can be up to 3 monolayers of titanium, strontium, strontium and oxygen, or titanium and oxygen. A layer 66 of a monocrystalline compound semiconductor material is then deposited overlying capping layer 64 by a process of molecular beam epitaxy. The deposition of layer 66 is initiated by depositing a layer of gallium onto capping layer 64. This initial step is followed by depositing arsenic and gallium to form monocrystalline gallium arsenide 66. Alternatively, barium or a mix of barium and strontium can be substituted for strontium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, pseudomorphic high electron mobility transistor (PHEMT), or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a strontium (or barium) titanate layer 65 and a gallium arsenide layer 66, similar devices can be fabricated using other substrates, monocrystalline oxide layers and other compound semiconductor layers as described elsewhere in this disclosure.

FIG. 14 illustrates a semiconductor structure 71 in accordance with a further embodiment. Structure 71 includes a monocrystalline semiconductor substrate 73 such as a monocrystalline silicon wafer that includes a region 75 and a region 76. A semiconductor component schematically illustrated by the dashed line 79 is formed in region 75 using conventional silicon device processing techniques commonly used in the semiconductor industry. Using process steps similar to those described above, a monocrystalline oxide layer 80 and an intermediate amorphous silicon oxide layer 83 are formed overlying region 76 of substrate 73. A template layer 84 and subsequently a monocrystalline semiconductor layer 87 are formed overlying monocrystalline oxide layer 80. In accordance with a further embodiment, an additional monocrystalline oxide layer 88 is formed overlying layer 87 by process steps similar to those used to form layer 80, and an additional monocrystalline semiconductor layer 90 is formed overlying monocrystalline oxide layer 88 by process steps similar to those used to form layer 87. In accordance with one embodiment, at least one of layers 87 and 90 is formed from a compound semiconductor material. Layers 80 and 83 may be subject to an annealing process as described above in connection with FIG. 3 to form a single amorphous accommodating layer.

A semiconductor component generally indicated by a dashed line 92 is formed at least partially in monocrystalline semiconductor layer 87. In accordance with one embodiment, semiconductor component 92 may include a field effect transistor having a gate dielectric formed, in part, by monocrystalline oxide layer 88. In addition, monocrystalline semiconductor layer 90 can be used to implement the gate electrode of that field effect transistor. In accordance with one embodiment, monocrystalline semiconductor layer 87 is formed from a group III-V compound and semiconductor component 92 is a radio frequency amplifier that takes advantage of the high mobility characteristic of group III-V component materials. In accordance with yet a further embodiment, an electrical interconnection schematically illustrated by the line 94 electrically interconnects component 79 and component 92. Structure 71 thus integrates components that take advantage of the unique properties of the two monocrystalline semiconductor materials.

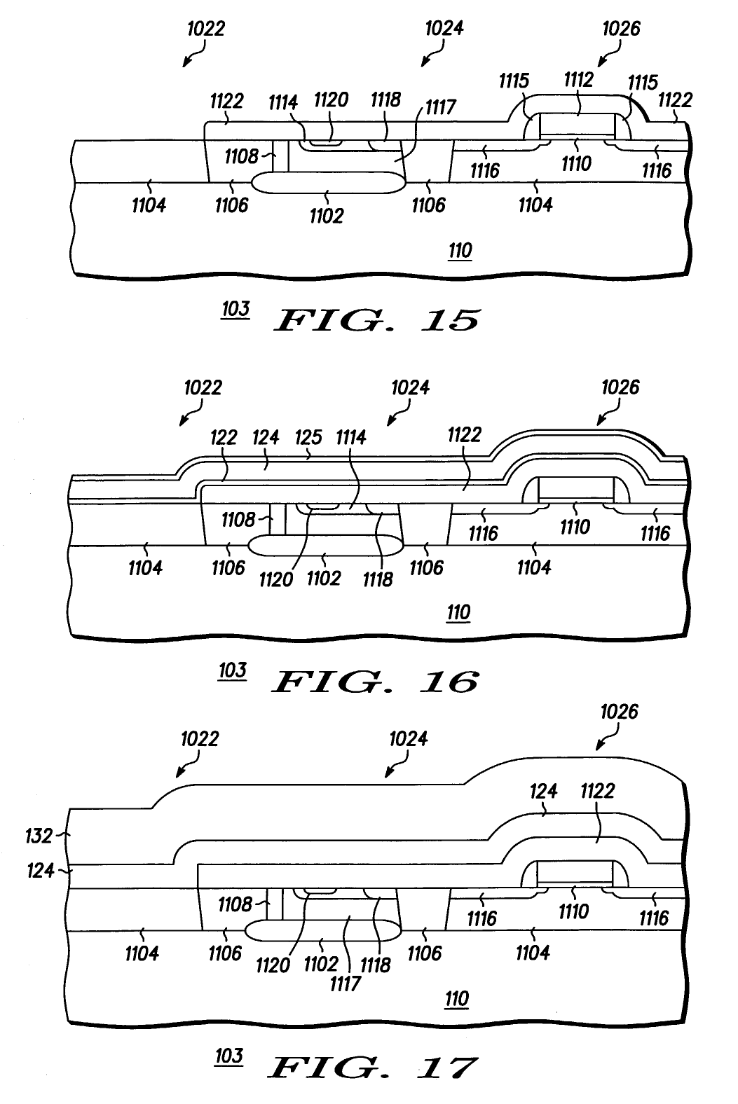

Attention is now directed to a method for forming exemplary portions of illustrative composite semiconductor structures or composite integrated circuits like 50 or 71. In particular, the illustrative composite semiconductor structure or integrated circuit 103 shown in FIGS. 15-19 includes a compound semiconductor portion 1022, a bipolar portion 1024, and a MOS portion 1026. In FIG. 15, a p-type doped, monocrystalline silicon substrate 110 is provided having a compound semiconductor portion 1022, a bipolar portion 1024, and a MOS portion 1026. Within bipolar portion 1024, the monocrystalline silicon substrate 110 is doped to form an N⁺ buried region 1102. A lightly p-type doped epitaxial monocrystalline silicon layer 1104 is then formed over the buried region 1102 and the substrate 110. A doping step is then performed to create a lightly n-type doped drift region 1117 above the N⁺ buried region 1102. The doping step converts the dopant type of the lightly p-type epitaxial layer within a section of the bipolar region 1024 to a lightly n-type monocrystalline silicon region. A field isolation region 1106 is then formed between and around the bipolar portion 1024 and the MOS portion 1026. A gate dielectric layer 1110 is formed over a portion of the epitaxial layer 1104 within MOS portion 1026, and the gate electrode 1112 is then formed over the gate dielectric layer 1110. Sidewall spacers 1115 are formed along vertical sides of the gate electrode 1112 and gate dielectric layer 1110.

A p-type dopant is introduced into the drift region 1117 to form an active or intrinsic base region 1114. An n-type, deep collector region 1108 is then formed within the bipolar portion 1024 to allow electrical connection to the buried region 1102. Selective n-type doping is performed to form N⁺ doped regions 1116 and the emitter region 1120. N⁺ doped regions 1116 are formed within layer 1104 along adjacent sides of the gate electrode 1112 and are source, drain, or source/drain regions for the MOS transistor. The N⁺ doped regions 1116 and emitter region 1120 have a doping concentration of at least 1E19 atoms per cubic centimeter to allow ohmic contacts to be formed. A p-type doped region is formed to create the inactive or extrinsic base region 1118 which is a P⁺ doped region (doping concentration of at least 1E19 atoms per cubic centimeter).

In the embodiment described, several processing steps have been performed but are not illustrated or further described, such as the formation of well regions, threshold adjusting implants, channel punchthrough prevention implants, field punchthrough prevention implants, as well as a variety of masking layers. The formation of the device up to this point in the process is performed using conventional steps. As illustrated, a standard N-channel MOS transistor has been formed within the MOS region 1026, and a vertical NPN bipolar transistor has been formed within the bipolar portion 1024. Although illustrated with a NPN bipolar transistor and an N-channel MOS transistor, device structures and circuits in accordance with various embodiments may additionally or alternatively include other electronic devices formed using the silicon substrate. As of this point, no circuitry has been formed within the compound semiconductor portion 1022.

After the silicon devices are formed in regions 1024 and 1026, a protective layer 1122 is formed overlying devices in regions 1024 and 1026 to protect devices in regions 1024 and 1026 from potential damage resulting from device formation in region 1022. Layer 1122 may be formed of, for example, an insulating material such as silicon oxide or silicon nitride.

All of the layers that have been formed during the processing of the bipolar and MOS portions of the integrated circuit, except for epitaxial layer 1104 but including protective layer 1122, are now removed from the surface of compound semiconductor portion 1022. A bare silicon surface is thus provided in the manner set forth above for the subsequent processing of this portion, for example in the manner set forth below.

An accommodating buffer layer 124 is then formed over the substrate 110 as illustrated in FIG. 16. The accommodating buffer layer will form as a monocrystalline layer over the properly prepared (i.e., having the appropriate template layer) bare silicon surface in portion 1022. The portion of layer 124 that forms over portions 1024 and 1026, however, may be polycrystalline or amorphous because it is formed over a material that is not monocrystalline, and therefore, does not nucleate monocrystalline growth. The accommodating buffer layer 124 typically is a monocrystalline metal oxide or nitride layer and typically has a thickness in a range of approximately 2-100 nanometers. In one particular embodiment, the accommodating buffer layer is approximately 3-10 nm thick. During the formation of the accommodating buffer layer, an amorphous intermediate layer 122 is formed along the uppermost silicon surfaces of form a single amorphous accommodating layer. If only a portion of layer 132 is formed prior to the anneal process, the remaining portion may be deposited onto structure 103 prior to further processing.

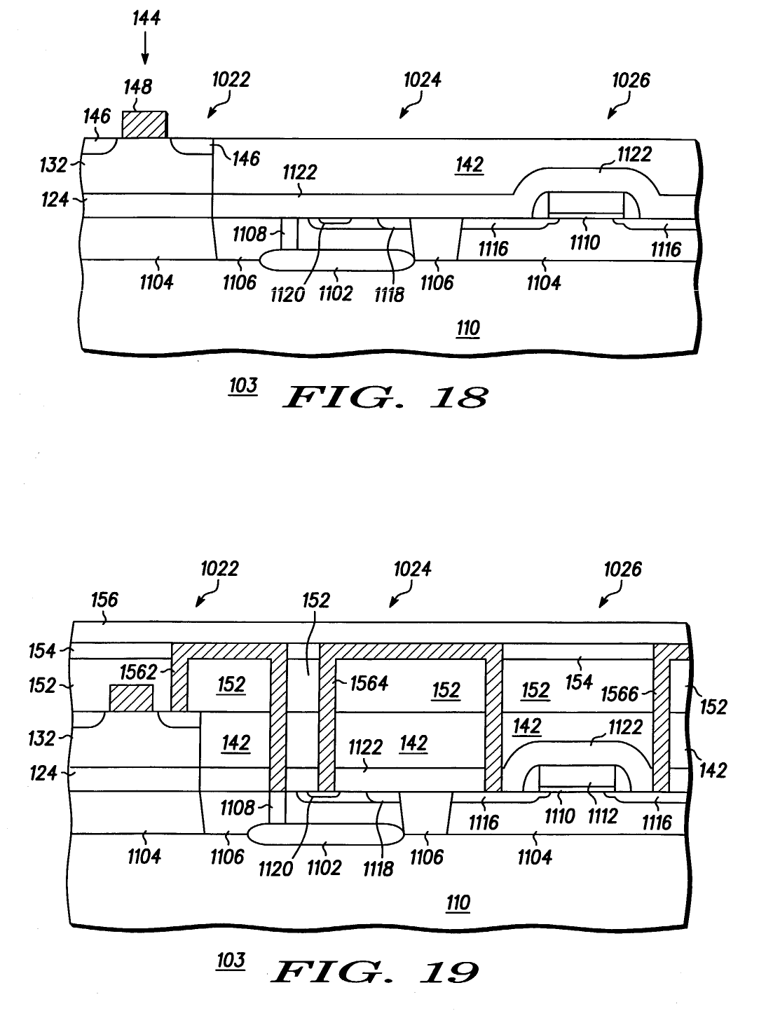

At this point in time, sections of the compound semiconductor layer 132 and the accommodating buffer layer 124 (or of the amorphous accommodating layer if the annealing process described above has been carried out) are removed from portions overlying the bipolar portion 1024 and the MOS portion 1026 as shown in FIG. 18. After the section of the compound semiconductor layer and the accommodating buffer layer 124 are removed, an insulating layer 142 is formed over protective layer 1122. The insulating layer 142 can include a number of materials such as oxides, nitrides, oxynitrides, low-k dielectrics, or the like. As used herein, low-k is a material having a dielectric constant no higher than approximately 3.5. After the insulating layer 142 has been deposited, it is then polished or etched to remove portions of the insulating layer 142 that overlie monocrystalline compound semiconductor layer 132.

A transistor 144 is then formed within the monocrystalline compound semiconductor portion 1022. A gate electrode 148 is then formed on the monocrystalline compound semiconductor layer 132. Doped regions 146 are then formed within the monocrystalline compound semiconductor layer 132. In this embodiment, the transistor 144 is a metal-semiconductor field-effect transistor (MESFET). If the MESFET is an n-type MESFET, the doped regions 146 and at least a portion of monocrystalline compound semiconductor layer 132 are also n-type doped. If a p-type MESFET were to be formed, then the doped regions 146 and at least a portion of monocrystalline compound semiconductor layer 132 would have just the opposite doping type. The heavier doped (N⁺) regions 146 allow ohmic contacts to be made to the monocrystalline compound semiconductor layer 132. At this point in time, the active devices within the integrated circuit have been formed. Although not illustrated in the drawing figures, additional processing steps such as formation of well regions, threshold adjusting implants, channel punchthrough prevention implants, field punchthrough prevention implants, and the like may be performed in accordance with the present invention. This particular embodiment includes an n-type MESFET, a vertical NPN bipolar transistor, and a planar n-channel MOS transistor. Many other types of transistors, including P-channel MOS transistors, p-type vertical bipolar transistors, p-type MESFETs, and combinations of vertical and planar transistors, can be used. Also, other electrical components, such as resistors, capacitors, diodes, and the like, may be formed in one or more of the portions 1022, 1024, and 1026.

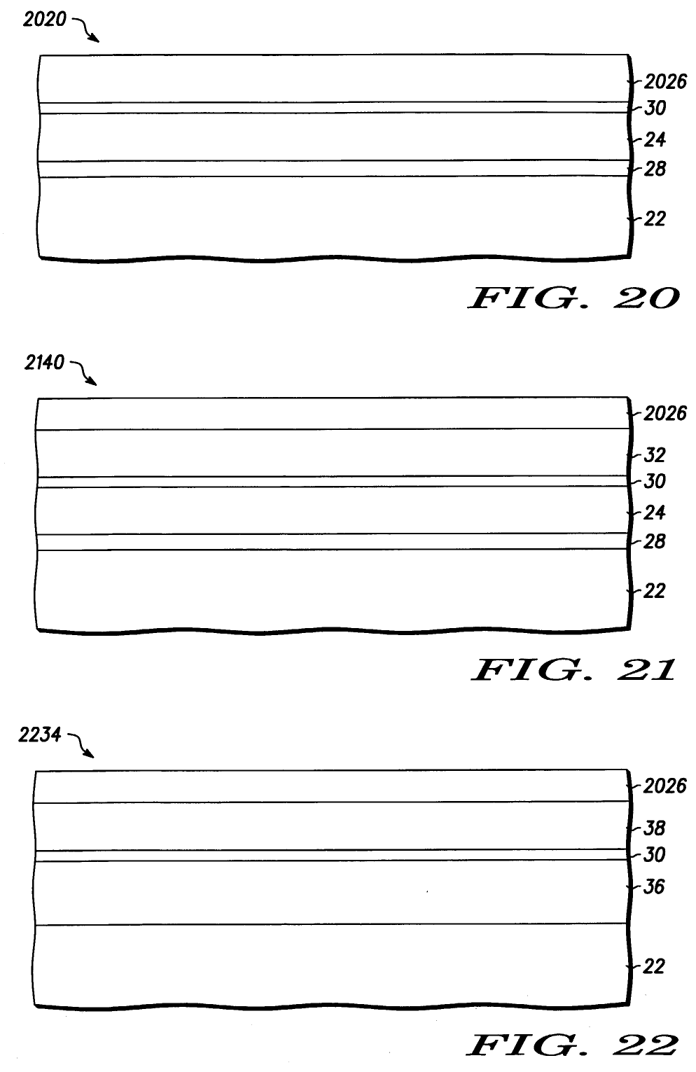

Processing continues to form a substantially completed integrated circuit 103 as illustrated in FIG. 19. An insulating layer 152 is formed over the substrate 110. The insulating layer 152 may include an etch-stop or polish-stop region that is not illustrated in FIG. 19. A second insulating layer 154 is then formed over the first insulating layer 152. Portions of layers 154, 152, 142, 124, and 1122 are removed to define contact openings where the devices are to be interconnected. Interconnect trenches are formed within insulating layer 154 to provide the lateral connections between the contacts. As illustrated in FIG. 19, interconnect 1562 connects a source or drain region of the n-type MESFET within portion 1022 to the deep collector region 1108 of the NPN transistor within the bipolar portion 1024. The emitter region 1120 of the NPN transistor is connected to one of the doped regions 1116 of the n-channel MOS transistor within the MOS portion 1026. The other doped region 1116 is electrically connected to other portions of the integrated circuit that are not shown. Similar electrical connections are also formed to couple regions 1118 and 1112 to other regions of the integrated circuit.

A passivation layer 156 is formed over the interconnects 1562, 1564, and 1566 and insulating layer 154. Other electrical connections are made to the transistors as illustrated as well as to other electrical or electronic components within the integrated circuit 103 but are not illustrated in the FIGS. Further, additional insulating layers and interconnects may be formed as necessary to form the proper interconnections between the various components within the integrated circuit 103.

As can be seen from the previous embodiment, active devices for both compound semiconductor and Group IV semiconductor materials can be integrated into a single integrated circuit. Because there is some difficulty in incorporating both bipolar transistors and MOS transistors within a same integrated circuit, it may be possible to move some of the components within bipolar portion 1024 into the compound semiconductor portion 1022 or the MOS portion 1026. Therefore, the requirement of special fabricating steps solely used for making a bipolar transistor can be eliminated. Therefore, there would only be a compound semiconductor portion and a MOS portion to the integrated circuit.

Turning to the next figure, FIG. 20 illustrates schematically, in cross section, a portion of a semiconductor structure 2020 in accordance with an embodiment of the invention. Semiconductor structure 2020 in FIG. 20 is similar to semiconductor structure 20 in FIG. 1. Semiconductor structure 2020 includes monocrystalline substrate 22, accommodating buffer layer 24 comprising a monocrystalline material, and a monocrystalline piezoelectric material layer 2026. In accordance with one embodiment of the invention, semiconductor structure 2020 can optionally include amorphous interface layer 28 positioned between monocrystalline substrate 22 and accommodating buffer layer 24. Semiconductor structure 2020 may also include template layer 30 between accommodating buffer layer 24 and monocrystalline piezoelectric material layer 2026.

The material for monocrystalline piezoelectric material layer 2026 can be selected, as desired, for a particular structure or application. For example, the monocrystalline piezoelectric material of monocrystalline piezoelectric material layer 2026 can consist of a lead-based perovskite material including, but not limited to, lead zirconate titanate (e.g., Pb(ZrₓTi₁₋ₓ)O₃ where x is 0 to 1 and preferably 0.2 to 0.6, lead lanthanum zirconate titanate (e.g., (Pb_{z}La_{1-z})(ZrₓTi₁₋ₓ)O₃ where x is 0 to 1 and preferably 0.2 to 0.6 and z is 0 to 1 and preferably 0 to 0.2, and lead magnesium niobate—lead titanate (e.g. PB (MgₓNb₁₋ₓ)O₃—PbTiO₃) where x is 0 to 1 and preferably 0.2 to 0.4, can also consist of lithium niobate (e.g., LiNbO₃), lithium tantalate (LiTaO₃), barium titanate (e.g., BaTiO₃), and gallium nitride (GaN) with or without magnesium doping, and can further consist of materials comprising any of these aforementioned materials. Suitable materials for template layer 30, when present in semiconductor structure 2020, chemically bond to selected sites of the surface of accommodating buffer layer 24 and provide sites for the nucleation of the epitaxial growth of monocrystalline piezoelectric material layer 2026.

The monocrystalline piezoelectric material of monocrystalline piezoelectric material layer 2026 can have a Curie temperature of less than approximately one thousand degrees Celsius to make monocrystalline piezoelectric material layer 2026 compatible with conventional semiconductor materials when semiconductor structure 2020 is integrated onto the same semiconductor chip as a discrete semiconductor transistor or an integrated circuit. In one embodiment, the monocrystalline piezoelectric material of monocrystalline piezoelectric material layer 2026 has a Curie temperature of less than or equal to approximately two hundred degrees Celsius. Also in this embodiment, the monocrystalline piezoelectric material of monocrystalline piezoelectric material layer 2026 is a poled ferroelectric material. Accordingly, as used in the Detailed Description of the Drawings and in the claims herein, the term “piezoelectric material” includes both inherently piezoelectric material and ferroelectric material that can be poled to exhibit piezoelectric characteristics.

FIG. 21 illustrates, in cross section, a portion of a semiconductor structure 2140 in accordance with a further embodiment of the invention. Semiconductor structure 2140 in FIG. 21 is similar to semiconductor structure 40 in FIG. 2. Semiconductor structure 2140 in FIG. 21 is also similar to the previously described semiconductor structure 2020 in FIG. 20, except that an additional buffer layer is positioned between accommodating buffer layer 24 and monocrystalline piezoelectric material layer 2026. More specifically, buffer layer 32 is positioned between template layer 30 and monocrystalline piezoelectric material layer 2026. Buffer layer 32 can be formed of a semiconductor material, a metal oxide material, or a metal nitride material to provide lattice compensation for monocrystalline piezoelectric material layer 2026 when the lattice constant of accommodating buffer layer 24 cannot be adequately matched to that of monocrystalline piezoelectric material layer 2026.

FIG. 22 schematically illustrates, in cross section, a portion of a semiconductor structure 2234 in accordance with another exemplary embodiment of the invention. Semiconductor structure 2234 in FIG. 22 is similar to semiconductor structure 34 in FIG. 3. Semiconductor structure 2234 in FIG. 22 is also similar to semiconductor structure 2020 in FIG. 20, except for two differences. First, semiconductor structure 2234 includes amorphous layer 36, rather than accommodating buffer layer 24 (FIG. 20) and amorphous interface layer 28 (FIG. 20), and second, semiconductor structure 2234 includes an additional monocrystalline layer, specifically monocrystalline layer 38, between optional template layer 30 and monocrystalline piezoelectric material layer 2026.

Semiconductor structures 2020 and 2140 of FIGS. 20 and 21, respectively, are adequate for forming a monocrystalline piezoelectric material layer over a monocrystalline substrate. However, semiconductor structure 2234 of FIG. 22, which includes, for example, the transformation of at least a portion of a monocrystalline accommodating buffer layer into an amorphous oxide layer, may be better for growing monocrystalline piezoelectric material layers because semiconductor structure 2234 of FIG. 22 allows strain in monocrystalline piezoelectric material layer 2026 to relax.

In accordance with one embodiment of the present invention, monocrystalline layer 38 serves as an anneal cap during formation of amorphous layer 36 and also serves as a template for the subsequent formation of monocrystalline piezoelectric material layer 2026. Therefore, monocrystalline layer 38 is preferably thick enough to provide a suitable template for the growth of at least one monolayer of monocrystalline piezoelectric material layer 2026, and monocrystalline layer 38 is also preferably thin enough to allow monocrystalline layer 38 to form as a substantially defect-free monocrystalline material.

In accordance with another embodiment of the invention, monocrystalline layer 38 can be eliminated from semiconductor structure 2234 of FIG. 22. In other words, the semiconductor structure in accordance with this embodiment only includes one monocrystalline layer disposed above amorphous layer 36.

The following non-limiting example illustrates a combination of materials useful in semiconductor structure 2020 in FIG. 20 in accordance with one embodiment of the invention. The example is merely illustrative, and it is not intended that the invention be limited to this illustrative example.

In accordance with one embodiment of the invention illustrated in FIG. 20, monocrystalline substrate 22 is a silicon substrate typically <001>{100} oriented. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1, and amorphous interface layer 28 is a layer of silicon oxide (SiOₓ) formed at the interface between monocrystalline substrate 22 and accommodating buffer layer 24. The value of z is selected to obtain one or more lattice constants closely matched to corresponding lattice constants of the subsequently formed monocrystalline piezoelectric material layer 2026.

The lattice structure of accommodating buffer layer 24 can exhibit a substantially forty-five degree rotation with respect to the lattice structure of monocrystalline substrate 22. Accommodating buffer layer 24 can have a thickness of about two to about one hundred nm and preferably has a thickness of about five to ten nm. In general, it is desired to have an accommodating buffer layer thick enough to isolate monocrystalline piezoelectric material layer 2026 from monocrystalline substrate 22 to obtain the desired electrical and acoustic properties in monocrystalline piezoelectric material layer 2026. Thicker layers may be fabricated, if needed. Amorphous interface layer 28 can have a thickness of about one half to five nm, and preferably a thickness of about one to two nm.

In accordance with one embodiment of the invention, monocrystalline piezoelectric material layer 2026 has a thickness of approximately 100 nm to several micrometers. The thickness of monocrystalline piezoelectric material layer 2026 generally depends on the application for which the layer is being prepared.

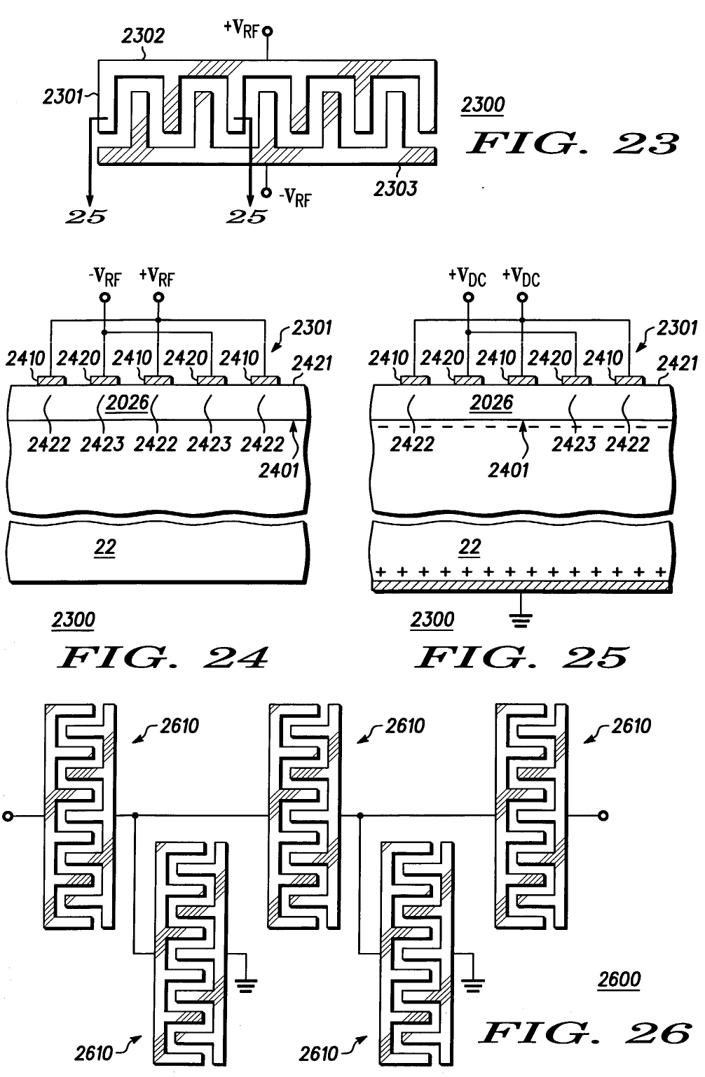

FIG. 23 shows a simplified top view of a surface acoustic wave transducer 2300 in accordance with an embodiment of the invention. Surface acoustic wave transducer 2300 can be of a type commonly employed as a fundamental building block in a surface acoustic wave device. Surface acoustic wave transducer 2300 includes interdigitated electrodes 2301 that are fabricated on a smooth surface of a piezoelectric material by, as an example, depositing a thin film of metallic material such as aluminum, applying and patterning a photo-definable material, and then etching the aluminum. Electrodes 2301 are electrically coupled alternately to a first terminal 2302 and to a second terminal 2303. Electrodes 2301 are typically periodic and define a characteristic acoustic wavelength at which surface acoustic wave transducer 2300 resonates at a characteristic center frequency upon application of electrical energy. Electrodes 2301 typically have a width that is one-fourth of this characteristic acoustic wavelength and are spaced with a pitch that is one-half of this characteristic acoustic wavelength, although other designs are possible. Electrical stimulation in an appropriate range of frequencies applied to terminals 2302 and 2303, and hence to electrodes 2301, results in surface acoustic waves being generated within surface acoustic wave transducer 2300, where such surface acoustic waves can be propagated outside of surface acoustic wave transducer 2300.

FIG. 24 illustrates a cross-sectional view of a portion of surface acoustic wave transducer 2300 in accordance with an embodiment of the invention. The cross-sectional view of FIG. 24 is taken along a section line 25-25 in FIG. 23.

As illustrated in FIG. 24, surface acoustic wave transducer 2300 comprises, among other features, monocrystalline piezoelectric material layer 2026. Monocrystalline piezoelectric material layer 2026 can be formed over a monocrystalline perovskite oxide material and an amorphous oxide material, both of which can be formed over a monocrystalline silicon substrate, as illustrated in FIGS. 20, 21, and 22 and as collectively represented in FIG. 24 by region 2401. In one embodiment of this example, monocrystalline piezoelectric material layer 2026 can be formed on the monocrystalline perovskite oxide material.

As described earlier with reference to FIG. 23, surface acoustic wave transducer 2300 also comprises electrodes 2301, which comprise two pluralities of electrodes 2410 and 2420 interdigitated with each other, as illustrated in FIG. 24. Accordingly, electrodes 2301 can form a portion of an interdigitated transducer (IDT) to control the surface acoustic wave in monocrystalline piezoelectric material layer 2026. Electrodes 2410 are electrically shorted to each other, overlie a surface 2421 of monocrystalline piezoelectric material layer 2026, and overlie portions 2422 of monocrystalline piezoelectric material layer 2026. Electrodes 2420 are electrically shorted to each other, overlie surface 2421 of monocrystalline piezoelectric material layer 2026, overlie portions 2423 of monocrystalline piezoelectric material layer 2026, and are interdigitated with electrodes 2410. As explained earlier, electrodes 2410 and 2420 can comprise an electrically conductive material, such as a metal, that is compatible with surface acoustic wave applications. Preferably, electrodes 2410 and 2420 are comprised of the same electrically conductive material and are fabricated simultaneously with each other.

In one embodiment of surface acoustic wave transducer 2300, the monocrystalline piezoelectric material layer 2026 is comprised of a ferroelectric material that is poled, as illustrated in FIG. 25.

In the preferred embodiment, this poling is accomplished by the temporary application of a single direct current (DC) voltage to all of interdigitated electrodes 2301 with respect to a ground potential at the bottom of monocrystalline substrate 22. Because the material for monocrystalline substrate 22 is semiconducting, free charged carriers will adjust so that an electrical field is formed across the ferroelectric material due to the application of the DC voltage. In some cases, the poling process may require the ferroelectric material to be heated to a poling temperature in the range of twenty-five to two hundred degrees Celsius, which can substantially reduces the time required to pole the ferroelectric material. The temperature may then be reduced substantially below the poling temperature, after which the DC voltage may be removed. In the embodiment illustrated in FIG. 25, the substrate is n-type so that a positive DC voltage is applied, and the negatively charged carriers appear at the top surface of monocrystalline substrate 22. One skilled in the art will understand that a negative DC voltage can also be applied to electrodes 2301 in certain situations. In a second embodiment, the poling process would occur after the application of the aluminum film, but prior to patterning and etching electrodes 2301. In this case, the DC voltage would be applied to the whole metal thin film with respect to the backside of monocrystalline substrate 22, and after the poling process is completed, electrodes 2301 are photo-defined as before. This second embodiment of the poling process may be advantageous for mass production of surface acoustic wave transducer 2300.

As an example, surface acoustic wave transducer 2300 can be a portion of a radio frequency (RF) surface acoustic wave device, the active portion of which can comprise (1) a first portion overlying monocrystalline piezoelectric material layer 2026 and (2) a second portion located in monocrystalline piezoelectric material layer 2026. The RF surface acoustic wave device can be a RF resonator and/or a RF surface acoustic wave filter. As an example, the RF acoustic wave filter can be a RF bandpass filter.

FIG. 26 depicts a circuit schematic of a surface acoustic wave device 2600. Surface acoustic wave device 2600 can have a ladder-type configuration, as illustrated in FIG. 26. Surface acoustic wave device 2600 obtains the desired frequency response through the electrical interconnection of surface acoustic wave transducers 2610 that are designed to resonate at particular characteristic frequencies. These resonances exhibit themselves in their terminal impedance magnitude response as so-called poles and zeroes that are manipulated by known techniques to produce the desired filter response. This type of surface acoustic wave filter is advantageous for certain cellular telephone applications, but is only one example of many possible surface acoustic wave filter configurations. For example, (1) the transducers comprising a ladder-type filter may include surface acoustic wave reflectors to improve their performance, (2) the surface acoustic wave filter may consist of interconnected transducers and physically configured so that the surface acoustic wave energy is transmitted and/or received by other transducers, thus creating and employing surface acoustic wave tracks, (3) adjacent surface acoustic wave tracks may be coupled by various means to further improve or restrict their performance, including transverse acoustic coupling, electrical coupling, and reflective coupling, among others, (4) filters employing surface acoustic wave tracks may have their frequency response further refined by the use of surface acoustic wave reflectors that constrain the surface acoustic wave energy into regions known as cavities and may also use various coupler techniques that adjust the amount of energy coupled between cavities, and (5) surface acoustic wave filters may also include inputs and outputs that are electrically balanced or unbalanced.

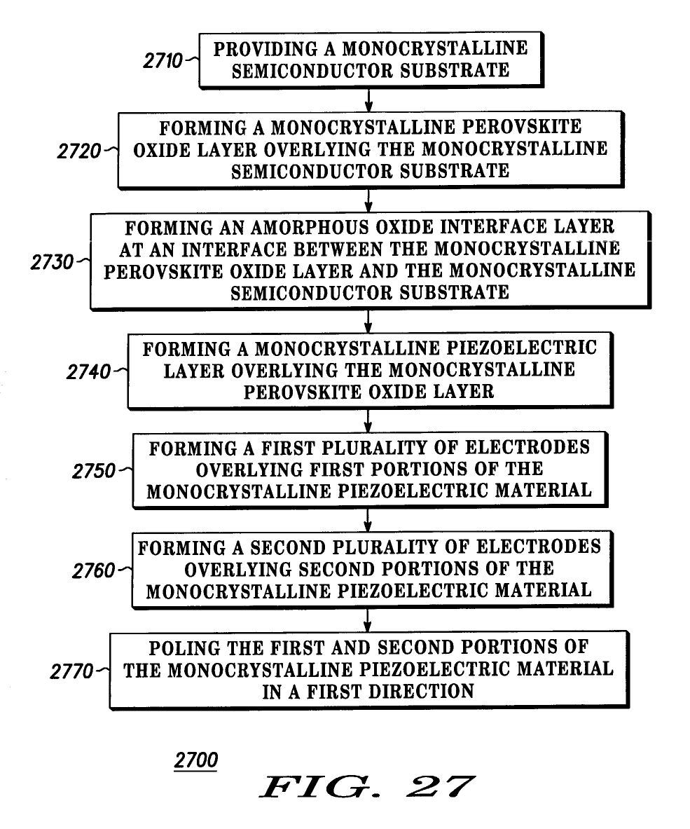

FIG. 27 illustrates a flow chart 2700 of a process for fabricating a semiconductor structure and surface acoustic wave device in accordance with an embodiment of the invention. As an example, the semiconductor structure of flow chart 2700 in FIG. 27 can be similar to semiconductor structures 2020, 2140, and/or 2234 in FIGS. 20, 21, and 22, respectively. As another example, the surface acoustic wave device of flow chart 2700 in FIG. 27 can be similar to surface acoustic wave transducer 2300 in FIGS. 23, 24, and 25 and/or surface acoustic wave device 2600 in FIG. 26.

At a step 2710 of flow chart 2700 in FIG. 27, a monocrystalline semiconductor substrate is provided. As an example, the monocrystalline semiconductor substrate of step 2710 can be similar to monocrystalline substrate 22 in FIGS. 20, 21, and 22.

Next, at a step 2720 of flow chart 2700 in FIG. 27, a monocrystalline perovskite oxide layer is formed overlying the monocrystalline silicon substrate. In one embodiment, the monocrystalline perovskite oxide layer can be deposited or epitaxially grown. The monocrystalline perovskite oxide layer has a thickness less than that which would result in strain-induced defects. As an example, the monocrystalline perovskite oxide layer can be similar to accommodating buffer layer 24 in FIGS. 20 and 21.

Then, at a step 2730 of flow chart 2700 in FIG. 27, an amorphous oxide interface layer containing at least silicon and oxygen is formed at an interface between the monocrystalline perovskite oxide layer and the monocrystalline semiconductor substrate. As an example, the amorphous oxide interface layer can be similar to amorphous interface layer 28 in FIGS. 20 and 21.

Subsequently, at a step 2740 of flow chart 2700 in FIG. 27, a monocrystalline piezoelectric layer is formed overlying the monocrystalline perovskite oxide layer. In one embodiment, the monocrystalline piezoelectric layer is deposited or epitaxially grown using any suitable thin film deposition technique such as, for example, solution gelation (sol-gel), RF sputtering, metal organic deposition (MOD), MBE, CVD, MOCVD, MEE, ALE, PVD, CSD, PLD, or the like. The monocrystalline piezoelectric layer can be epitaxially deposited on the monocrystalline perovskite oxide film, and can be epitaxially grown to a thickness of approximately one hundred nm to several micrometers, but preferably approximately two-tenths to two micrometers. After being deposited or epitaxially grown, the monocrystalline piezoelectric layer can be heated, preferably at a temperature less than or equal to the Curie temperature of the monocrystalline piezoelectric layer.

The monocrystalline piezoelectric layer has a top surface and is preferably comprised of a ferroelectric material. As an example, the monocrystalline piezoelectric layer can be similar to monocrystalline piezoelectric material layer 2026 in FIGS. 20, 21, 22, 24, and 25. Furthermore, the top surface of the monocrystalline piezoelectric layer in step 2740 of FIG. 27 can be similar to surface 2421 in FIGS. 24 and 25.

Next, at a step 2750 of flow chart 2700 in FIG. 27, a first plurality of electrodes are formed. The electrodes are electrically shorted to each other, overlie the surface of the monocrystalline piezoelectric layer, and overlie first portions of the monocrystalline piezoelectric material. As an example, the electrodes can be similar to electrodes 2410 in FIGS. 23, 24, and 25. Furthermore, the first portions of the monocrystalline piezoelectric material in step 2750 of FIG. 27 can be similar to portions 2422 of monocrystalline piezoelectric material layer 2026 in FIGS. 24 and 25. In one embodiment, the electrodes can be a first portion of a radio frequency surface acoustic wave device overlying the monocrystalline piezoelectric material.

Then, at a step 2760 of flow chart in FIG. 27, a second plurality of electrodes are formed. Steps 2750 and 2760 can be performed simultaneously with each other. The electrodes of step 2760 are electrically shorted to each other, overlie the surface of the monocrystalline piezoelectric material, overlie second portions of the monocrystalline piezoelectric material, and are interdigitated with the electrodes of step 2750. As an example, the electrodes of step 2760 can be similar to electrodes 2420 in FIGS. 23, 24, and 25. Furthermore, the second portions of the monocrystalline piezoelectric material in step 2760 of FIG. 27 can be similar to portions 2423 of monocrystalline piezoelectric material layer 2026 in FIGS. 24 and 25. In one embodiment, the electrodes of step 2760 can be a second portion of a radio frequency acoustic wave device overlying the monocrystalline piezoelectric material.

If the monocrystalline piezoelectric layer is comprised of a ferroelectric material, then it is subsequently poled. The poling orients dipoles in the monocrystalline piezoelectric layer when the monocrystalline piezoelectric layer is comprised of a ferroelectric material. The poling process can be achieved by applying a DC voltage to the monocrystalline piezoelectric layer to produce a polarization pattern in the monocrystalline piezoelectric layer.

More specifically, at an optional step 2770 of flow chart 2700 in FIG. 27, the first and second portions of the monocrystalline piezoelectric layer are poled in a first direction. As an example, the first direction can be substantially perpendicular to the surface of the monocrystalline piezoelectric material. Step 2770 can be performed by applying a DC voltage pulse to the first and second portions of the monocrystalline piezoelectric material at room temperature or a temperature of approximately twenty-five to two hundred degrees Celsius to polarize the first and second portions of the monocrystalline piezoelectric material in the first direction. The voltage pulse can be applied to the first and second portions of the monocrystalline piezoelectric material via the electrodes of step 2750. In a different embodiment, step 2770 can be performed during steps 2750 and/or 2760.

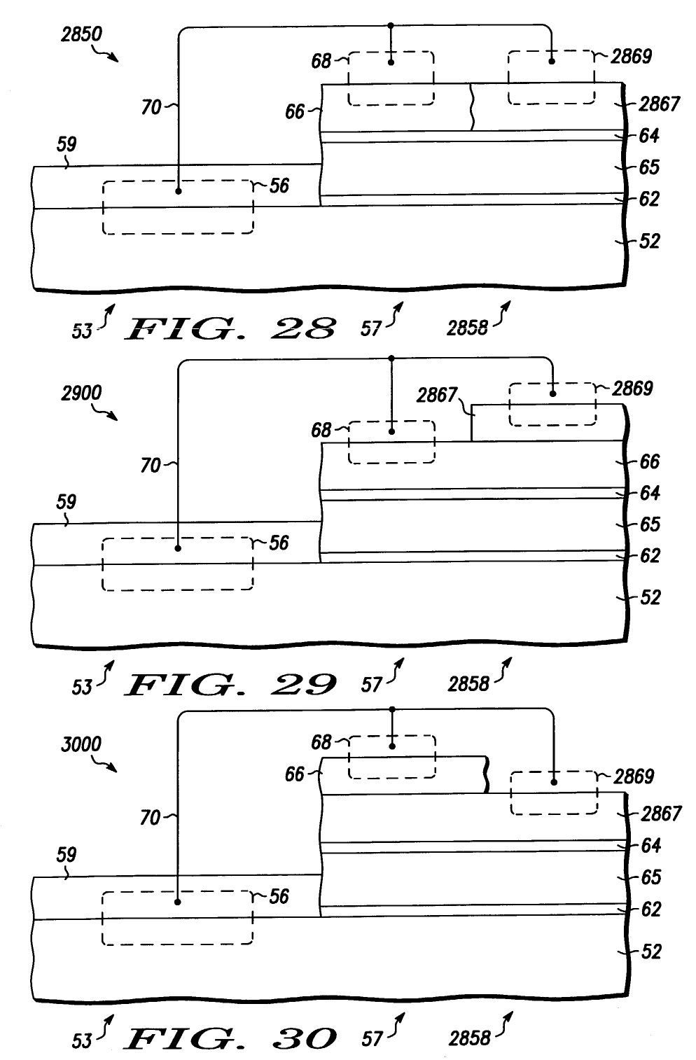

FIG. 28 illustrates schematically, in cross section, a device, semiconductor structure, or integrated circuit 2850 in accordance with a further embodiment. Integrated circuit 2850 in FIG. 28 is similar to device structure 50 in FIG. 13. Integrated circuit 2850 includes monocrystalline semiconductor substrate 52 with two regions, namely regions 57 and 2858. Monocrystalline semiconductor substrate 52 can also comprise a third region, i.e., region 53, which is optional.

An optional semiconductor component generally indicated by dashed line 56 can be formed in and over in region 53. The optional semiconductor component can be a resistor, a capacitor, an active electrical component such as a diode or a transistor, an optoelectric component such as a photo detector, or an integrated circuit such as a CMOS, bipolar, or BiCMOS integrated circuit. For example, the optional semiconductor component can be a CMOS integrated circuit configured to perform digital signal processing or another function for which silicon integrated circuits are well suited. The optional semiconductor component in region 53 can be formed by conventional semiconductor processing as well known and widely practiced in the semiconductor industry. Layer of insulating material 59, such as a layer of silicon dioxide or the like, may overlie the optional semiconductor component.

If the optional semiconductor component is formed in region 53, insulating material 59 and any other layers that may have been formed or deposited during the processing of the optional semiconductor component in region 53 are removed from the surface of regions 57 and 2858 to provide a bare silicon surface in those regions. As is well known, bare silicon surfaces are highly reactive and a native silicon oxide layer can quickly form on the bare surface. A layer (preferably 1-3 monolayers) of strontium or strontium and oxygen is deposited onto the native oxide layer on the surface of regions 57 and 2858 and is reacted with the oxidized surface to form a first template layer (not shown). In accordance with one embodiment, a monocrystalline oxide layer is formed overlying the template layer by a process of molecular beam epitaxy. Reactants including strontium, titanium, and oxygen are deposited onto the template layer to form the monocrystalline oxide layer. Initially during the deposition, the partial pressure of oxygen is preferably kept near the minimum necessary to fully react with the strontium and titanium to form a monocrystalline strontium titanate layer. The partial pressure of oxygen is then increased to provide an overpressure of oxygen and to allow oxygen to diffuse through the growing monocrystalline oxide layer. The oxygen diffusing through the strontium titanate reacts with silicon at the surface of region 57 to form an amorphous layer of silicon oxide 62 on regions 57 and 2858 and at the interface between monocrystalline semiconductor substrate 52 and monocrystalline oxide layer 65. Monocrystalline oxide layer 65 and the amorphous layer of silicon oxide 62 may be subject to an annealing process as described above in connection with FIG. 3 to form a single amorphous accommodating layer.

In accordance with an embodiment, the step of depositing the monocrystalline oxide layer 65 can be terminated by depositing capping layer 64, which can be comprised of up to 3 monolayers of titanium, strontium, strontium and oxygen, or titanium and oxygen. Layer 66 of a monocrystalline compound semiconductor material is then deposited overlying capping layer 64 by a process of molecular beam epitaxy. The deposition of layer 66 is initiated by depositing a layer of gallium onto capping layer 64. This initial step is followed by depositing arsenic and gallium to form monocrystalline gallium arsenide for layer 66. Alternatively, barium or a mix of barium and strontium can be substituted for strontium in the above example.

A semiconductor component, generally indicated by dashed line 68, is formed in and over layer 66 and over region 57. The semiconductor component can be formed by processing steps conventionally used in the fabrication of gallium arsenide or other III-V compound semiconductor material devices. The semiconductor component can be one or more active or passive components, and preferably comprises a semiconductor laser, light emitting diode, photodetector, heterojunction bipolar transistor (HBT), high frequency MESFET, pseudomorphic high electron mobility transistor (PHEMT), an integrated circuit comprised of any of the foregoing, or other component that utilizes and takes advantage of the physical properties of compound semiconductor materials.

Layer 66 and any other layers that may have been formed or deposited during the processing of the semiconductor component over region 57 are removed from the surface of capping layer 64. Next, a monocrystalline piezoelectric material layer 2867(not shown in figure) is formed over region 2858 and on capping layer 64. The specific process used to form monocrystalline piezoelectric material layer 2867 can be similar to that described earlier with reference to other monocrystalline piezoelectric material layers such as, for example, monocrystalline piezoelectric material layer 2026 in FIG. 20. In a different embodiment, prior the formation of monocrystalline piezoelectric material layer 2867, one or more of capping layer 64, monocrystalline oxide layer 65, and the amorphous layer of silicon oxide 62 may need to be removed and reformed, as needed, to enable the formation of the monocrystalline structure of monocrystalline piezoelectric material layer 2867. In another embodiment, each of capping layer 64, monocrystalline oxide layer 65, and the amorphous layer of silicon oxide 62 can be removed, and a different buffer scheme can be formed prior to the formation of monocrystalline piezoelectric material layer 2867. An example of the different buffer scheme can include the scheme described earlier with reference to FIG. 20. As illustrated in FIG. 28, layer 66 is absent over and under monocrystalline piezoelectric material layer 2867.

In FIG. 28, a surface acoustic wave device, generally indicated by dashed line 2869 is formed in and over monocrystalline piezoelectric material layer 2867 and over region 2858. The surface acoustic wave device can be formed by processing steps similar to that described earlier with reference to other surface acoustic wave devices such as, for example, surface acoustic wave transducer 2300 in FIGS. 23, 24, and 25 or surface acoustic wave device 2600 in FIG. 26. The surface acoustic wave device in FIG. 28 can be comprised of one or more surface acoustic wave transducers. In a different embodiment, monocrystalline piezoelectric material layer 2867 and the surface acoustic wave device indicated by dashed line 2869 can be formed before layer 66 and/or the semiconductor component indicated by dashed line 68.

A metallic conductor or interconnect structure schematically indicated by line 70 can be formed to electrically couple the semiconductor component indicated by dashed line 68, the optional semiconductor component indicated by dashed line 56, and the acoustic wave device indicated by dashed line 2869, thus implementing an integrated circuit that includes at least one surface acoustic wave device and at least one compound semiconductor component. Integrated circuit 2850 thus integrates components that take advantage of the unique properties of at least a monocrystalline semiconductor compound material and a piezoelectric material. Although integrated circuit 2850 has been described as a structure formed on a monocrystalline silicon substrate and having a monocrystalline strontium (or barium) titanate layer and a monocrystalline gallium arsenide layer, similar devices can be fabricated using other substrates, oxide layers, compound semiconductor layers, and piezoelectric layers, as described elsewhere in this disclosure.

FIG. 29 illustrates schematically, in cross section, a device, semiconductor structure, or integrated circuit 2900 in accordance with a further embodiment. Integrated circuit 2900 in FIG. 29 is similar to integrated circuit 2850 in FIG. 28, except that layer 66 and monocrystalline piezoelectric material layer 2867 in FIG. 28 are laterally adjacent to each other while the same layers in FIG. 29 are vertically adjacent to each other. As illustrated in FIG. 29, monocrystalline piezoelectric material layer 2867 is formed over and, in fact, on layer 66. Accordingly, layer 66 is located under monocrystalline piezoelectric material layer 2867. Layer 66 and the semiconductor component indicated by dashed line 68 can be formed before monocrystalline piezoelectric material layer 2867 and the surface acoustic wave device indicated by dashed line 2869. A buffer scheme such as, for example, the scheme described earlier with reference to FIG. 20 can be formed over layer 66 and under monocrystalline piezoelectric material layer 2867.

FIG. 30 illustrates schematically, in cross section, a device, semiconductor structure, or integrated circuit 3000 in accordance with another embodiment. Integrated circuit 3000 in FIG. 30 is similar to integrated circuit 2850 in FIG. 28, except that layer 66 and monocrystalline piezoelectric material layer 2867 in FIG. 28 are laterally adjacent to each other while the same layers in FIG. 30 are vertically adjacent to each other. As illustrated in FIG. 30, layer 66 is formed over and, in fact, on monocrystalline piezoelectric material layer 2867. Accordingly, monocrystalline piezoelectric material layer 2867 is located under layer 66. Monocrystalline piezoelectric material layer 2867 and the surface acoustic wave device indicated by dashed line 2869 can be formed before layer 66 and the semiconductor component indicated by dashed line 68. A buffer scheme such as, for example, one of the schemes described earlier with reference to FIGS. 1, 2, and 3 can be formed over monocrystalline piezoelectric material layer 2867 and under layer 66.

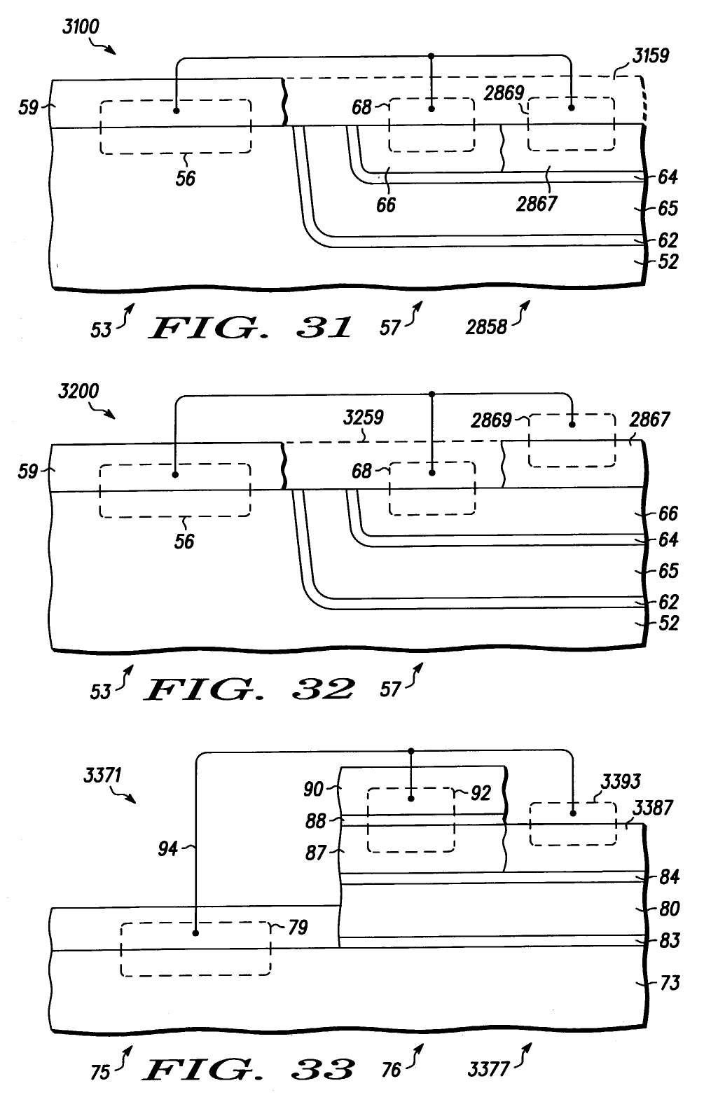

FIG. 31 illustrates schematically, in cross section, a device, semiconductor structure, or integrated circuit 3100 in accordance with yet another embodiment.

Integrated circuit 3100 in FIG. 31 is similar to integrated circuit 2850 in FIG. 28, except that layer 66 and monocrystalline piezoelectric material layer 2867 in FIG. 28 are formed over a top surface of monocrystalline semiconductor substrate 52 while the same layers in FIG. 31 are formed in a recess in the top surface of monocrystalline semiconductor substrate 52. As illustrated in FIG. 31, layer 66 is formed laterally adjacent to monocrystalline piezoelectric material layer 2867 such that the top surfaces of layer 66 and monocrystalline piezoelectric material layer 2867 are substantially planar with the top surface of monocrystalline semiconductor substrate 52. This planar configuration alleviates problems associated with non-planarity during semiconductor device manufacturing. Examples of such problems that are alleviated by the planar configuration include, for example, step coverage problems, photoresist pattern development problems, and etching problems.

Insulating material 59 can be formed after forming the semiconductor component indicated by dashed line 68 and the surface acoustic wave device indicated by 2869 and can be located over the same, as shown in FIG. 31 by a dashed line 3159. Furthermore, the various embodiments described with reference to integrated circuit 2850 in FIG. 28 can also be applied here to integrated circuit 3100 in FIG. 31.

In a different embodiment, each of layer 66 and monocrystalline piezoelectric material layer 2867 can be located in a different recess in the top surface of monocrystalline semiconductor substrate 52, and the top surface of each of such layers can be planar with the top surface of monocrystalline semiconductor substrate 52. In another embodiment, one of layer 66 or monocrystalline piezoelectric material layer 2867 can be located in a recess of and can have a top surface planar with the top surface of a first region of monocrystalline semiconductor substrate 52 while the other layer can be located over the top surface of a second region of monocrystalline semiconductor substrate 52.

FIG. 32 illustrates schematically, in cross section, a device, semiconductor structure, or integrated circuit 3200 in accordance with a further embodiment. Integrated circuit 3200 in FIG. 32 is similar to integrated circuit 2900 in FIG. 29 and integrated circuit 3100 in FIG. 31, except that layer 66 and monocrystalline piezoelectric material layer 2867 in FIG. 28 are formed over a top surface of monocrystalline semiconductor substrate 52 while layer 66 in FIG. 32 is formed in a recess in the top surface of monocrystalline semiconductor substrate 52 and monocrystalline piezoelectric material layer 2867 is formed over layer 66. As illustrated in FIG. 32, layer 66 is formed vertically adjacent to monocrystalline piezoelectric material layer 2867 such that the top surface of layer 66 and the bottom surface of monocrystalline piezoelectric material layer 2867 are substantially planar with the top surface of monocrystalline semiconductor substrate 52.

Insulating material 59 can be formed after forming the semiconductor component indicated by dashed line 68 and can be located over the same, as shown in FIG. 31 by a dashed line 3259. In another embodiment, insulating material 59 can also be located over the surface acoustic wave device indicated by dashed line 2869. Furthermore, the various embodiments described with reference to integrated circuit 2900 in FIG. 29 can also be applied here to integrated circuit 3200 in FIG. 32.

In a different embodiment of integrated circuit 3200 in FIG. 32, the recess in the top surface of monocrystalline semiconductor substrate 52 can be deeper such that the top surface of monocrystalline piezoelectric material layer 2867 is planar with the top surface of monocrystalline semiconductor substrate 52. In another embodiment of integrated circuit 3200 in FIG. 32, layer 66 is located over monocrystalline piezoelectric material layer 2867 such that the top surface of monocrystalline piezoelectric material layer 2867 and the bottom surface of layer 66 can be formed to be substantially planar with the top surface of monocrystalline semiconductor substrate 52. One skilled in the art will also understand that the concepts of integrated circuit 3000 in FIG. 30 can also be applied to the various embodiments of integrated circuit 3200 in FIG. 32.

FIG. 33 illustrates a device, semiconductor structure, or integrated circuit 3371 in accordance with a further embodiment. Integrated circuit 3371 is similar to semiconductor structure 71 in FIG. 14. Integrated circuit 3371 includes monocrystalline semiconductor substrate 73 such as a monocrystalline silicon wafer that includes regions two regions, namely 76 and 3377. Monocrystalline semiconductor substrate 73 can also include a third region, i.e., region 75, which is optional.

An optional semiconductor component schematically illustrated by dashed line 79 can be formed in and over region 75 using conventional silicon device processing techniques commonly used in the semiconductor industry. The optional semiconductor component indicated by dashed line 79 can be similar to the optional semiconductor component indicated by dashed line 56 in FIG. 28. Using process steps similar to those described above, monocrystalline oxide layer 80 and amorphous silicon oxide layer 83 in FIG. 33 are formed overlying regions 76 and 3377 of monocrystalline semiconductor substrate 73. Template layer 84 and subsequently monocrystalline semiconductor layer 87 are formed overlying monocrystalline oxide layer 80. In accordance with a further embodiment, optional monocrystalline oxide layer 88 can be formed overlying monocrystalline semiconductor layer 87 by process steps similar to those used to form monocrystalline oxide layer 80, and optional monocrystalline semiconductor layer 90 is formed overlying monocrystalline oxide layer 88 by process steps similar to those used to form monocrystalline semiconductor layer 87. In accordance with one embodiment, at least one of monocrystalline semiconductor layers 87 and 90 is formed from a compound semiconductor material. Monocrystalline oxide layer 80 and amorphous silicon oxide layer 83 may be subject to an annealing process as described above in connection with FIG. 3 to form a single amorphous accommodating layer.

The semiconductor component generally indicated by dashed line 92 is formed in and over monocrystalline semiconductor layer 87. In accordance with one embodiment, the semiconductor component may include one or more field effect transistors, each having a gate dielectric formed, in part, by monocrystalline oxide layer 88. In addition, monocrystalline semiconductor layer 90 can be used to implement the gate electrodes of the field effect transistors. In accordance with one embodiment, monocrystalline semiconductor layers 87 and 90 are formed from a group III-V compound semiconductor, and the semiconductor component is a radio frequency amplifier that takes advantage of the high mobility characteristic of group III-V component materials.

Monocrystalline semiconductor layers 87 and 90, monocrystalline oxide layer 88, and any other layers that may have been formed or deposited during the processing of the semiconductor component over region 76 are removed from the surface of template layer 84. Next, a monocrystalline piezoelectric material layer 3387 is formed over region 3377 and on template layer 84. The specific process used to form monocrystalline piezoelectric material layer 3387 can be similar to that described earlier with reference to other monocrystalline piezoelectric material layers such as, for example, monocrystalline piezoelectric material layer 2026 in FIG. 20. In a different embodiment, prior the formation of monocrystalline piezoelectric material layer 3387, one or more of template layer 84, monocrystalline oxide layer 80, and amorphous silicon oxide layer 83 may need to be removed and reformed, as needed, to enable the formation of the monocrystalline structure of monocrystalline piezoelectric material layer 3387. In another embodiment, each of template layer 84, monocrystalline oxide layer 80, and amorphous silicon oxide layer 83 can be removed, and a different buffer scheme can be formed prior to the formation of monocrystalline piezoelectric material layer 3387. An example of the different buffer scheme can include the scheme described earlier with reference to FIG. 20. As illustrated in FIG. 33, monocrystalline semiconductor layers 87 and 90 and monocrystalline oxide layer 88 are absent over and under monocrystalline piezoelectric material layer 3387.

In FIG. 33, a surface acoustic wave device, generally indicated by dashed line 3393, is formed in and over monocrystalline piezoelectric material layer 3387 and over region 3377. The surface acoustic wave device can be formed by processing steps similar to that described earlier with reference to other surface acoustic wave devices such as, for example, surface acoustic wave transducer 2300 in FIGS. 23, 24, and 25 and surface acoustic wave device 2600 in FIG. 26. The surface acoustic wave device can be comprised of one or more surface acoustic wave transducers. In a different embodiment, monocrystalline piezoelectric material layer 3387 and the surface acoustic wave device indicated by dashed line 3393 can be formed before monocrystalline semiconductor layers 90 and 87, monocrystalline oxide layer 88, and the semiconductor component indicated by dashed line 92.

In accordance with yet a further embodiment, the electrical interconnection or interconnect structure schematically illustrated by line 94 electrically interconnects the optional semiconductor component indicated by dashed line 79, the semiconductor component indicated by dashed line 92, and the surface acoustic wave device indicated by dashed line 3393. Integrated circuit 3371 thus integrates components that take advantage of the unique properties of at least a monocrystalline compound semiconductor material and a piezoelectric material. Such integration also improves the electromechanical coupling of the various components.

The various embodiments of integrated circuit 2850 in FIG. 28 that are illustrated in FIGS. 29 through 32 can also be applied to integrated circuit 3371 in FIG. 33. In view of the more complicated nature of integrated circuit 3371 in FIG. 33 compared to integrated circuit 2850 in FIG. 28, one skilled in the art will understand, after viewing the disclosure related to FIGS. 28 through 33, that many other variations of piezoelectric material overlying or underlying semiconductor materials also exist. For example, monocrystalline piezoelectric material layer 3387 can overlie monocrystalline semiconductor layer 87 or both monocrystalline semiconductor layers 87 and 90. Therefore, for simplicity and brevity, these other variations are not explicitly described in detail herein, but one skilled in the art will understand these variations.

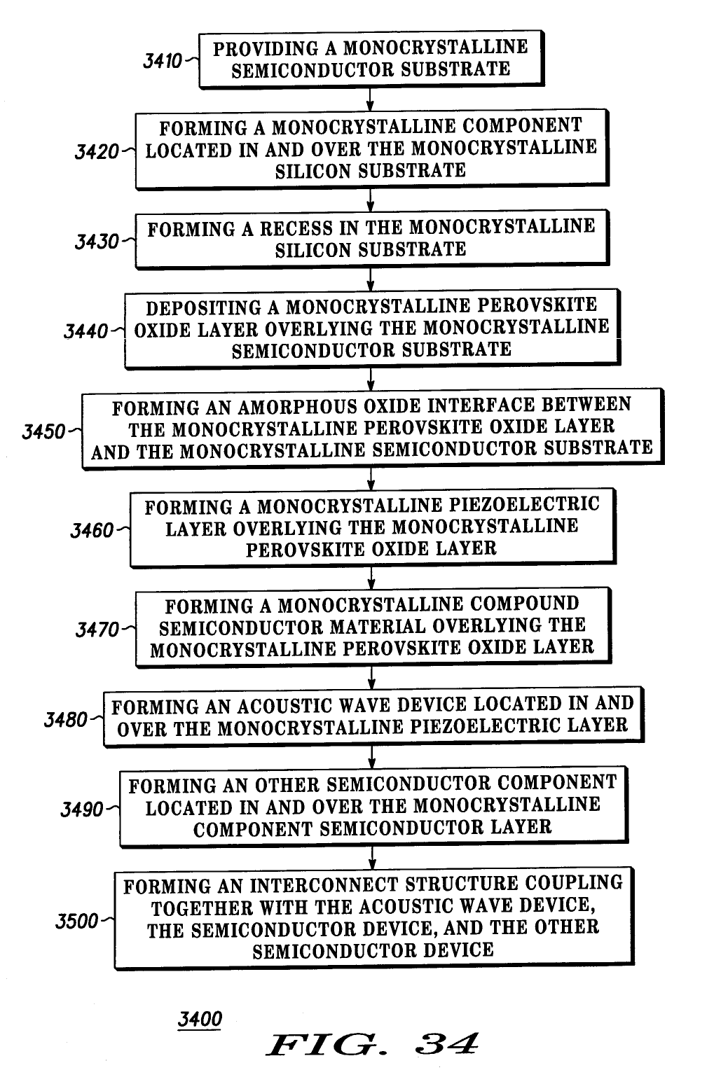

FIG. 34 illustrates a flow chart 3400 of a process for fabricating an integrated circuit. As an example, the integrated circuit of flow chart 3400 in FIG. 34 can be similar to integrated circuits 2850, 2900, 3000, 3100, 3200, and/or 3371 in FIGS. 28, 29, 30, 31, 32, and 33, respectively. At a step 3410 of flow chart 3400, a monocrystalline semiconductor substrate is provided. As an example, the monocrystalline semiconductor substrate can be similar to monocrystalline semiconductor substrate 52 in FIGS. 28 through 32 and/or to monocrystalline semiconductor substrate 73 in FIG. 33.

At an optional step 3420 in flow chart 3400 of FIG. 34, a semiconductor component can be formed in and over the monocrystalline silicon substrate. As an example, the semiconductor component can be similar to the semiconductor component indicated by dashed line 56 in FIGS. 28 through 32 and/or dashed line 79 in FIG. 33. Then, at an optional step 3430 of flow chart 3400 in FIG. 34, a recess can be formed in monocrystalline silicon substrate. As an example, the recess can be similar to the recess described with reference to, and as illustrated in, FIGS. 31 and/or 32.

Next, at a step 3440 in flow chart 3400 in FIG. 34, a monocrystalline perovskite oxide layer is formed overlying the monocrystalline semiconductor substrate. As an example, the monocrystalline perovskite oxide layer can be similar to monocrystalline oxide layer 65 in FIGS. 28 through 32 and/or monocrystalline oxide layer 80 in FIG. 33. Subsequently, at a step 3450 in flow chart 3400 in FIG. 34, an amorphous oxide interface layer is formed at an interface between the monocrystalline perovskite oxide layer and the monocrystalline semiconductor substrate. As an example, the amorphous oxide interface layer can contain at least silicon and oxygen and can be similar to silicon oxide 62 in FIGS. 28 through 32 and/or amorphous silicon oxide layer 83 in FIG. 33.

Then, at a step 3460 in flow chart 3400 of FIG. 34, a monocrystalline piezoelectric layer is formed overlying the monocrystalline perovskite oxide layer. As an example, the monocrystalline piezoelectric layer can be similar to monocrystalline piezoelectric material layer 2867 in FIGS. 28 through 32 and/or monocrystalline piezoelectric material layer 3387 in FIG. 33. Next, at a step 3470 in flow chart 3400 of FIG. 34, a monocrystalline compound semiconductor layer is formed overlying the monocrystalline perovskite oxide layer. As an example, the monocrystalline compound semiconductor layer can be similar to layer 66 in FIGS. 28 through 32 and/or monocrystalline semiconductor layers 87 and 90 in FIG. 33.

Subsequently, at a step 3480 in flow chart 3400 of FIG. 34, a surface acoustic wave device is formed in and over the monocrystalline piezoelectric layer. As an example, the surface acoustic wave device can be similar to the surface acoustic wave device indicated by dashed line 2869 in FIGS. 28 through 32 and/or dashed line 3393 in FIG. 33. Next, at a step 3490 in flow chart 3400 of FIG. 34, a semiconductor component is formed in and over the monocrystalline compound semiconductor layer. As an example, the semiconductor component can be similar to the semiconductor component indicated by dashed line 68 in FIGS. 28 through 32 and/or dashed line 92 in FIG. 33.

Then, at a step 3500 in flow chart 3400 of FIG. 34, an interconnect structure is formed coupling together the surface acoustic wave device, the semiconductor component, and the other semiconductor component. As an example, the interconnect structure can be similar to the interconnect structure indicated by line 70 in FIGS. 28 through 32 and/or line 94 in FIG. 33.

One skilled in the art will understand that the sequence of the steps in flow chart 3400 in FIG. 34 can be altered from that depicted in FIG. 34 based on the various embodiments illustrated in FIGS. 28 through 33. For example, the sequence of steps 3480 and 3490 can be reversed. As another example, step 3480 can occur between steps 3460 and 3470. Additionally, step 3470 can occur before step 3460, and step 3490 can occur between newly sequenced steps 3470 and 3460. Many other variations exist, but are not explicitly mentioned here for simplicity and brevity.

Therefore, an improved integrated circuit having a surface acoustic wave device and a process for fabricating the same is provided to overcome the disadvantages of the prior art. The integrated circuit has a high quality monocrystalline piezoelectric layer over a monocrystalline layer such as a semiconductor substrate. The high quality monocrystalline piezoelectric layer has a lower manufacturing cost compared to the prior art while still providing comparable, if not superior, surface acoustic properties for acoustic wave propagation in the monocrystalline piezoelectric layer. A radio frequency or other high frequency output signal generated by the semiconductor component in the compound semiconductor layer and coupled to the surface acoustic wave device is improved and confined. The integrated circuit reduces the number of components needed in, for example, a portable device, and also reduces the size required in the portable device for such components, and further reduces the costs incurred in forming the individual components and assembling them onto a circuit board. Examples of suitable portable devices include cellular telephones, wireless personal digital assistants (PDAs), two-way pagers, two-way radios, and the like. The addition of optional CMOS control circuitry to the integrated circuit increases the functionality of the integrated circuit. A common silicon chip in a cellular telephone is a digital signal processor (DSP) commonly used to interpret a digital signal into voice or data. Therefore, the integrated circuits described herein can permit a single chip to transmit and/or receive a digital signal, interpret or de-construct the digital signal into an analog signal or vice versa, and output the signal to a speaker or an antenna.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. An apparatus comprising:
a monocrystalline silicon substrate;
an amorphous oxide material overlying the monocrystalline silicon substrate;
a monocrystalline perovskite oxide material overlying the amorphous oxide material;
a monocrystalline piezoelectric material overlying the monocrystalline perovskite oxide material; and
a surface acoustic wave device located in and over the monocrystalline piezoelectric material.

2. The apparatus of claim 1 further comprising:
a monocrystalline compound semiconductor material located under the monocrystalline piezoelectric material.

3. The apparatus of claim 1 further comprising:
a monocrystalline compound semiconductor material located over the monocrystalline piezoelectric material.

4. The apparatus of claim 1 further comprising:
a silicon semiconductor component located in and over the monocrystalline silicon substrate; and
an interconnect structure coupling the silicon semiconductor component and the surface acoustic wave device.

5. The apparatus of claim 3 further comprising:
a silicon semiconductor component located in and over the monocrystalline silicon substrate; and
an interconnect structure coupling the silicon semiconductor component and the surface acoustic wave device.

6. The apparatus of claim 3 further comprising:
a compound semiconductor component located in the monocrystalline compound semiconductor material; and
an interconnect structure coupling the compound semiconductor component and the surface acoustic wave device.

7. The apparatus of claim 1 wherein:
the monocrystalline silicon substrate has a recess; and
the monocrystalline piezoelectric material is located in the recess.

8. The apparatus of claim 7 wherein:
the monocrystalline silicon substrate has a first surface;
the recess is located in the first surface;
the monocrystalline piezoelectric material has a second surface; and
the second surface is substantially planar with the first surface.

9. The apparatus of claim 8 wherein:
the monocrystalline compound semiconductor material is located under the monocrystalline piezoelectric material.

10. The apparatus of claim 8 wherein:
the monocrystalline compound semiconductor material is located over the monocrystalline piezoelectric material.

11. The apparatus of claim 2 wherein:
the monocrystalline silicon substrate has a recess; and
the monocrystalline compound semiconductor material is located in the recess.

12. The apparatus of claim 3 wherein:
the monocrystalline silicon substrate has a recess; and
the monocrystalline compound semiconductor material is located in the recess.

13. The apparatus of claim 11 wherein:
the monocrystalline silicon substrate has a first surface;
the recess is located in the first surface;
the monocrystalline compound semiconductor material has a second surface; and
the second surface is substantially planar with the first surface.

14. The apparatus of claim 12 wherein:
the monocrystalline silicon substrate has a first surface;
the recess is located in the first surface;
the monocrystalline compound semiconductor material has a second surface; and
the second surface is substantially planar with the first surface.

15. An apparatus comprising:
a monocrystalline silicon substrate;
an amorphous oxide layer overlying the monocrystalline silicon substrate;
a monocrystalline perovskite oxide layer overlying the amorphous oxide layer;
a monocrystalline ferroelectric and piezoelectric layer overlying the monocrystalline perovskite oxide layer; and
a surface acoustic wave device located in and over the monocrystalline ferroelectric and piezoelectric layer.

16. The integrated circuit of claim 15 further comprising:
a plurality of silicon semiconductor components located in and over the monocrystalline silicon substrate; and
an interconnect structure electrically coupling together the plurality of silicon semiconductor components and the surface acoustic wave device.

17. The integrated circuit of claim 15 wherein:
the monocrystalline silicon substrate has a recess; and
the monocrystalline ferroelectric and piezoelectric layer is located in the recess.

18. The integrated circuit of claim 17 wherein:
the monocrystalline silicon substrate has a first surface;
the recess is located in the first surface;
the monocrystalline ferroelectric and piezoelectric layer has a second surface; and
the second surface is substantially planar with the first surface.

19. The integrated circuit of claim 15 further comprising:
a monocrystalline compound semiconductor layer overlying the monocrystalline perovskite oxide layer.

20. The integrated circuit of claim 19 wherein:
the monocrystalline silicon substrate has a recess; and
the monocrystalline compound semiconductor layer is located in the recess.

21. The integrated circuit of claim 20 wherein:
the monocrystalline silicon substrate has a first surface;
the recess is located in the first surface;
the monocrystalline compound semiconductor layer has a second surface; and
the second surface is substantially planar with the first surface.

22. The integrated circuit of claim 20 wherein:
the monocrystalline silicon substrate has a different recess; and
the monocrystalline ferroelectric and piezoelectric layer is located in the different recess.

23. The integrated circuit of claim 22 wherein:
the monocrystalline silicon substrate has a first surface;
the recess and the different recess are located in the first surface;
the monocrystalline ferroelectric and piezoelectric layer has a second surface;
the monocrystalline compound semiconductor layer has a third surface; and
the first, second, and third surfaces are substantially planar with each other.

24. The integrated circuit of claim 23 further comprising:
a plurality of compound semiconductor components located in the compound semiconductor layer; and
an interconnect structure electrically coupling together the plurality of compound semiconductor components and the surface acoustic wave device.

25. A process for fabricating an integrated circuit comprising:
providing a monocrystalline silicon substrate;
depositing a monocrystalline perovskite oxide layer overlying the monocrystalline silicon substrate;
forming an amorphous oxide interface layer containing at least silicon and oxygen at an interface between the monocrystalline perovskite oxide layer and the monocrystalline silicon substrate;
forming a monocrystalline piezoelectric layer overlying the monocrystalline perovskite oxide layer; and
forming a surface acoustic wave device located in and over the monocrystalline piezoelectric layer

26. The process of claim 25 further comprising:
a monocrystalline compound semiconductor layer located under the monocrystalline piezoelectric layer.

27. The process of claim 25 further comprising:
a monocrystalline compound semiconductor layer located over the monocrystalline piezoelectric layer.

28. The process of claim 25 further comprising:
forming a silicon semiconductor component located in and over the monocrystalline silicon substrate; and
forming an interconnect structure coupling together the silicon semiconductor component and the surface acoustic wave device.

29. The process of claim 27 further comprising:
forming a silicon semiconductor component located in and over the monocrystalline silicon substrate; and
forming an interconnect structure coupling together the silicon semiconductor component and the surface acoustic wave device.

30. The process of claim 27 further comprising:
forming a compound semiconductor component located in the monocrystalline compound semiconductor material; and
forming an interconnect structure coupling together the compound semiconductor component and the surface acoustic wave device.

31. The process of claim 25 further comprising:
forming a recess in the monocrystalline silicon substrate,
wherein:
forming the monocrystalline piezoelectric layer further comprises:
forming the monocrystalline piezoelectric layer in the recess.

32. The process of claim 31 wherein:
the monocrystalline silicon substrate has a first surface;
the recess is located in the first surface;
the monocrystalline piezoelectric layer has a second surface; and
the second surface is substantially planar with the first surface.

33. The process of claim 32 wherein:
a monocrystalline compound semiconductor layer is located under the monocrystalline piezoelectric layer.

34. The process of claim 32 wherein:
a monocrystalline compound semiconductor layer is located over the monocrystalline piezoelectric layer.

35. The process of claim 33 wherein:
the monocrystalline silicon substrate has a recess; and
the monocrystalline compound semiconductor layer is located in the recess.

36. The process of claim 34 wherein:
the monocrystalline silicon substrate has a recess; and
the monocrystalline compound semiconductor layer is located in the recess.

37. The process of claim 36 wherein:
the monocrystalline silicon substrate has a first surface;
the recess is located in the first surface;
the monocrystalline compound semiconductor layer has a second surface; and
the second surface is substantially planar with the first surface.

38. The process of claim 36 wherein:
the monocrystalline silicon substrate has a first surface;
the recess is located in the first surface;
the monocrystalline compound semiconductor layer has a second surface; and
the second surface is substantially planar with the first surface.
